(19) United States
(12) Patent Application Publication
(10) Pub. No.: US 2015/0340466 A1
(43) Pub. Date: Nov. 26, 2015

(54) METHOD FOR MANUFACTURING SEMICONDUCTOR DEVICE AND DEVICE

(71) Applicant: FUJITSU SEMICONDUCTOR LIMITED, Yokohama-shi (JP)

(72) Inventors: Masahiro Fukuda, Yokohama (JP); Tomohiro Kubo, Akisima (JP)

(21) Appl. No.: 14/712,064

(22) Filed: May 14, 2015

(30) Foreign Application Priority Data
May 21, 2014 (JP) 2014-105036

(51) Int. Cl. H01L 29/66; H01L 29/78

(52) U.S. Cl. CPC H01L 29/66636; H01L 29/66545; H01L 29/7848

(57) ABSTRACT

A method for manufacturing a semiconductor device includes: forming a temporary gate electrode and a first dummy gate electrode located on a first side of the temporary gate electrode, on a semiconductor region with a first lattice constant; forming a first semiconductor layer with a second lattice constant different from the first lattice constant, between the temporary gate electrode and the first dummy gate electrode; removing the temporary gate electrode while leaving the first dummy gate electrode intact; and forming a gate electrode in a region from which the temporary gate electrode is removed.

### CROSS-REFERENCE TO RELATED APPLICATION

This application is based upon and claims the benefit of priority of the prior Japanese Patent Application No. 2014-105036, filed on May 21, 2014, the entire contents of which are incorporated herein by reference.

### FIELD

The embodiments discussed herein are related to a method for manufacturing a semiconductor device and a semiconductor device.

### BACKGROUND

When a strain is generated in a channel region of a MOS (Metal-Oxide-Semiconductor) Field Effect Transistor, mobility of carriers increases. As a method for generating the strain in the channel region of the MOS Field

Effect Transistor, known is a method of forming SiGe layers on both sides of the channel region formed in a Si substrate. When the SiGe layers are formed on both sides of the channel region, the strain is generated in the channel region due to a difference between a lattice constant of Si and that of SiGe.

In regard to the above method, reported is a technique for increasing a strain in the channel region by removing a gate electrode on the channel region after forming the SiGe layer (for example, S. Natarajan et al., “A 32 nm Logic Technology Featuring 2^{nd}—Generation High-k+Metal-Gate Transistors, Enhanced Channel Strain and 0.171 μm² SRAM Cell Size in a 291 Mb Array”, IEEE (IEDM2008 presentation material), p. 941-943, 2008). The gate electrode to be removed is a polysilicon electrode, for example. In a region from which the gate electrode is removed, a metal electrode is formed, for example. The above technique is also applicable to a FinFET (Fin Field Effect Transistor) (for example, G. Eneman et al., “Stress Simulation for Optimal Mobility Group IV p- and nMOS FinFETs for the 14 nm Node and Beyond”, IEDM2012-131, 2012.).

In addition, as a method for generating a strain in the channel region, also known is a technique of using a dummy gate electrode (for example, Japanese Laid-open Patent Publication NO. 2007-53336). According to this technique, the dummy gate electrode facing a gate electrode is provided, and an impurity (for example, carbon) is introduced into the dummy gate electrode so that the lattice constant of the dummy gate electrode is changed. By the change of the lattice constant, stress is generated on the dummy gate electrode, and the generated stress is transmitted to an active region to produce the strain in the channel region.

Furthermore, there is another report concerning the above techniques (for example, Joseph M Steigerwald, “Chemical Mechanical Polish: The Enabling Technology”, IEDM2008, 2008, pp.37-40.).

### SUMMARY

According to an aspect of the embodiments, a method for manufacturing a semiconductor device includes: forming a temporary gate electrode and a first dummy gate electrode located on a first side of the temporary gate electrode, on a semiconductor region with a first lattice constant; forming a first semiconductor layer with a second lattice constant different from the first lattice constant, between the temporary gate electrode and the first dummy gate electrode; removing the temporary gate electrode while leaving the first dummy gate electrode intact; and forming a gate electrode in a region from which the temporary gate electrode is removed.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A to 1C are plan views illustrating a method for manufacturing a semiconductor device according to the embodiment 1;

FIGS. 2A to 2C are plan views illustrating the method for manufacturing a semiconductor device according to the embodiment 1;

FIGS. 3A to 3C are plan views illustrating the method for manufacturing a semiconductor device according to the embodiment 1;

FIGS. 4A to 4C are plan views illustrating the method for manufacturing a semiconductor device according to the embodiment 1;

FIG. 5 is a plan view illustrating the method for manufacturing a semiconductor device according to the embodiment 1;

FIGS. 6A to 6C are section views illustrating the method for manufacturing a semiconductor device according to the embodiment 1;

FIGS. 7A to 7C are section views illustrating the method for manufacturing a semiconductor device according to the embodiment 1;

FIGS. 8A to 8C are section views illustrating the method for manufacturing a semiconductor device according to the embodiment 1;

FIGS. 9A to 9C are section views illustrating the method for manufacturing a semiconductor device according to the embodiment 1;

FIG. 10 is section view illustrating the method for manufacturing a semiconductor device according to the embodiment 1;

FIGS. 11A and 11B are diagrams illustrating the states of a channel region before and after the temporary gate electrode is removed;

FIGS. 12A and 12B are diagrams illustrating the states of the channel region before and after the temporary gate electrode is removed together with the first dummy gate electrode and the second dummy gate electrode;

FIG. 13 is a diagram illustrating the calculated values of tensile stresses applied to the channel region;

FIGS. 14A to 14C are section views illustrating models used for the calculation of FIG. 13;

FIG. 15 is a plan view of the Fins according to the embodiment 3;

FIGS. 16A and 16B are section views illustrating a forming process of the Fins along the Y-Y line depicted in FIG. 15;

FIGS. 17A to 17C are section views illustrating the forming process of the Fins along the Y-Y line depicted in FIG. 15;

FIGS. 18A to 18C are section views illustrating the forming process of the Fins along the Y-Y line depicted in FIG. 15;

FIGS. 19A and 19B are diagrams illustrating a forming process of active regions according to the embodiment 3;

FIGS. 20A to 20C are diagrams illustrating a forming process of the temporary gate electrode and the dummy gate electrode;

FIGS. 21A to 21C are diagrams illustrating the forming process of the temporary gate electrodes and the dummy gate electrodes;

FIGS. 22A to 22C are diagrams illustrating the forming process of the temporary gate electrodes and the dummy gate electrodes;

FIGS. 23A and 23B are diagrams illustrating a forming process of extension regions and pocket regions;

FIGS. 24A and 24B are diagrams illustrating a forming process of source/drain regions;

FIGS. 25A and 25B are diagrams illustrating the forming process of source/drain regions;

FIGS. 26A and 26B are diagrams illustrating the forming process of source/drain regions;

FIGS. 27A and 27B are diagrams illustrating the forming process of source/drain regions;

FIGS. 28A and 28B are diagrams illustrating a forming process of gate electrodes;

FIGS. 29A and 29B are diagrams illustrating the forming process of gate electrodes;

FIGS. 30A and 30B are diagrams illustrating the forming process of gate electrodes;

FIGS. 31A and 31B are diagrams illustrating the forming process of gate electrodes;

FIGS. 32A and 32B are diagrams illustrating the forming process of gate electrodes; and

FIGS. 33A to 33C are diagrams illustrating a modified example of the embodiment 3.

### DESCRIPTION OF EMBODIMENTS

As described previously, a strain in a channel region may be increased by removing a gate electrode.

However, the prior techniques for increasing strain have a problem wherein the strain is not sufficiently increased in the channel region just below the gate electrode in some cases.

According to the embodiments, a strain increased in a semiconductor region by removing of the gate electrode is concentrated in a semiconductor region just below the temporary gate electrode (for example, the channel region).

Preferred embodiments will be explained with reference to accompanying drawings. Here, identical symbols are given to corresponding parts even in different drawings, and the description thereof will be omitted.

### Embodiment 1

An embodiment 1 discloses a semiconductor device that includes an n-channel MOS Field Effect Transistor having a strain in a channel region (hereafter referred to as a strained channel NMOS transistor).

(1) Manufacturing Method

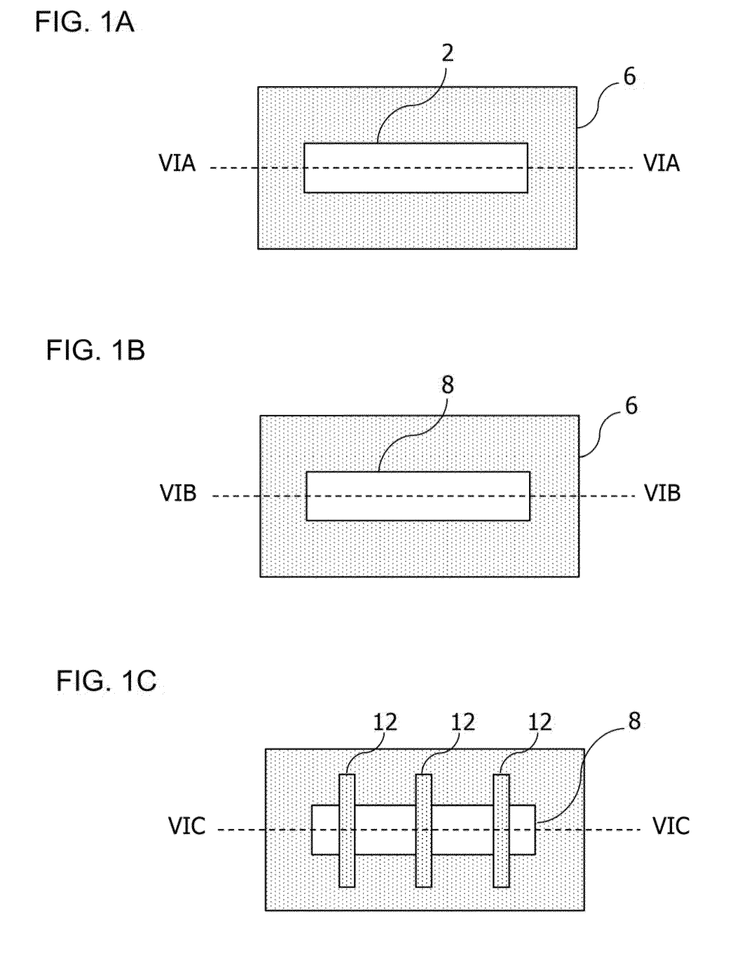

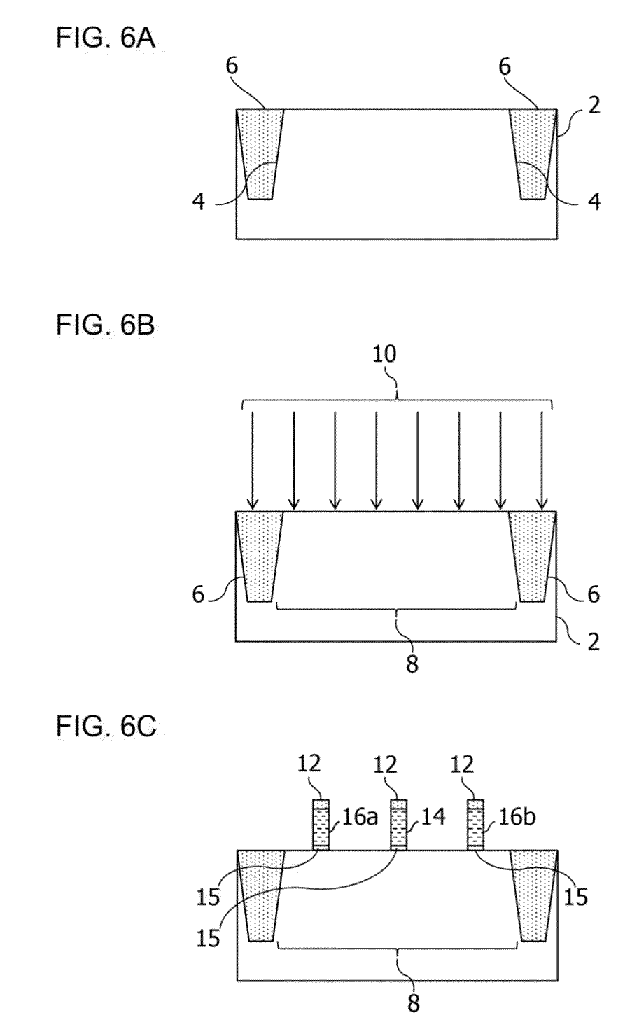

FIGS. 1A to 5 are plan views illustrating a method for manufacturing a semiconductor device according to the embodiment 1. FIGS. 6A to 10 are section views illustrating the method for manufacturing a semiconductor device according to the embodiment 1.

(1-1) Forming of Element Isolation Region (refer to FIGS. 1A and 6A)

FIG. 1A is a plan view illustrating a forming process of an element isolation region (Shallow Trench Isolation region, which is hereafter referred to as STI region). FIG. 6A is a section view along the VIA-VIA line depicted in FIG. 1A.

First, a thermal oxide film (not illustrated) of 2 nm to 10 nm (preferably 5 nm) in thickness is formed on a silicon substrate 2 (hereafter referred to as a Si substrate). Further, on the thermal oxide film, a silicon nitride (hereafter referred to as a SiN film; not illustrated) of a thickness of 50 nm to 100 nm is formed by LP-CVD (Low Pressure Chemical Vapor Deposition) or the like, for example. The plane orientation of the Si substrate 2 is preferably (100).

Next, the thermal oxide film and the SiN film are dry-etched through a resist film pattern (hereafter referred to as a resist pattern) to form a hard mask (not illustrated) including an aperture corresponding to the STI region. Through the hard mask, the semiconductor substrate 2 is dry-etched to form a trench 4 (refer to FIG. 6A) of 100 nm to 300 nm in depth. Thereafter, on the Si substrate 2 with the trench 4 formed thereon, an oxide film (hereafter referred to as a plasma oxide film; not illustrated) is deposited by plasma CVD.

Next, by a Chemical Mechanical Polishing (hereafter referred to as CMP) method, the plasma oxide film is polished until the aforementioned SiN film on the thermal oxide film is exposed. Consequently, formed is a plasma oxide film buried in the trench.

The plasma oxide film is heat-treated at 900-1000° C. so as to be densified. Consequently, a wet etching rate of the plasma oxide film is reduced. Thereafter, the thermal oxide film and the SiN film on the Si substrate 2 are removed by wet etching. The SiN film may be etched by phosphoric acid, for example. The silicon oxide film such as the thermal oxide film may be etched by a HF aqueous solution, for example.

In the aforementioned manner, an STI region 6 is formed as depicted in FIGS. 1A and 6A. The description of a numeric range “A-B” (for example, 2 nm-10 nm) signifies a range of A or greater and B or smaller (for example, 2 nm or greater and 10 nm or smaller).

Further, in FIGS. 1A and 6A, depicted is the Si substrate 2 and only a portion related to the strained channel NMOS transistor out of a structure formed on the Si substrate 2. The same is also applicable to other drawings.

(1-2) Forming Process of Active Region (refer to FIGS. 1B and 6B)

FIG. 1B is a plan view illustrating the forming process of an active region. FIG. 6B is a section view along the VIB-VIB line depicted in FIG. 1B.

First, the surface of the Si substrate 2 surrounded by the STI region 6 (refer to FIG. 6A) is oxidized to grow a sacrificial oxide film (not illustrated) of 2-10 nm (preferably, 5 nm) in thickness. Next, as depicted in FIG. 6B, ions 10 of a p-type impurity (for example, B) are injected into a surface layer 8 (that is, a semiconductor region) of the Si substrate 2 surrounded by the STI region 6.

Thereafter, heat treatment of the semiconductor region 8 (for example, Rapid Thermal Anneal) is performed to activate the injected impurity and restore damage in the semiconductor region 8. Consequently, a p-type semiconductor region (namely, p-type active region) is formed.

(1-3) Forming Process of Temporary Gate Electrode and Dummy Gate Electrode (refer to FIGS. 1C and 6C)

FIG. 1C is a plan view illustrating the forming process of a temporary gate electrode and a dummy gate electrode. FIG. 6C is a section view along the VIC-VIC line depicted in FIG. 1C.

First, the sacrificial oxide film is removed by wet etching. Thereafter, the surface of the semiconductor region 8 (refer to FIG. 6B) is oxidized to form, for example, a 1-3 nm oxide film (not illustrated). The oxide film comes to be a part of a gate insulating film described later.

On the oxide film, a polysilicon film (not illustrated) of 50 nm-200 nm in thickness (preferably, 100 nm) is formed by CVD (Chemical Vapor Deposition). It may also be possible to form an amorphous silicon film in place of the polysilicon film.

On this polysilicon film, deposited is an insulating film (for example, silicon oxide film (hereafter referred to as SiO film) or SiN film; not illustrated) of 25 nm-100 nm (preferably, 50 nm) in thickness, for example. Then, on the deposited insulating film, resist patterns (not illustrated) that have a certain width (for example, 10 nm-100 nm, preferably 20 nm-50 nm) and extend to a certain direction (preferably, [1-11] direction) are formed with a certain pitch (for example, 50 nm-200 nm) by means of immersion ArF lithography, for example. Through the resist patterns, the insulating film on the polysilicon film is etched to form hard masks 12.

Through the hard masks, the polysilicon film is etched by RIE (Reactive Ion Etching), for example. Consequently, as depicted in FIG. 6C, formed are a temporary gate electrode 14, a first dummy gate electrode 16a located on the first side of the temporary gate electrode 14, and a second dummy gate electrode 16b located on the second side of the temporary gate electrode 14, on the semiconductor region 8. Here, the second side is different from the first side. The temporary gate electrode 14 is an electrode corresponding to the gate electrode of the strained channel NMOS transistor. The side face of the temporary gate electrode 14 (a shorter side direction) is directed to the [011] direction of the semiconductor region 8.

Next, by means of wet etching, removed is a thermal oxide film (not illustrated) that covers the semiconductor region 8 and is exposed by the aforementioned RIE. At this time, some parts 15 of the thermal oxide film is left beneath the temporary gate electrode 14, the first dummy gate electrode 16a, and the second dummy gate electrode 16b. At this stage, hard masks 12 used in RIE are left.

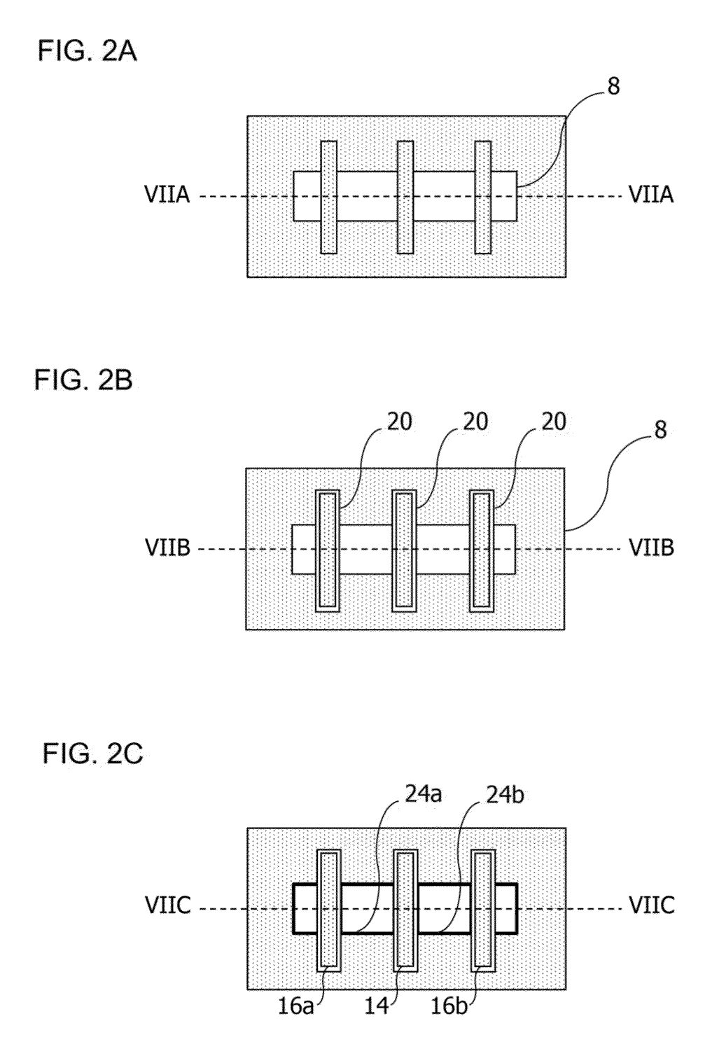

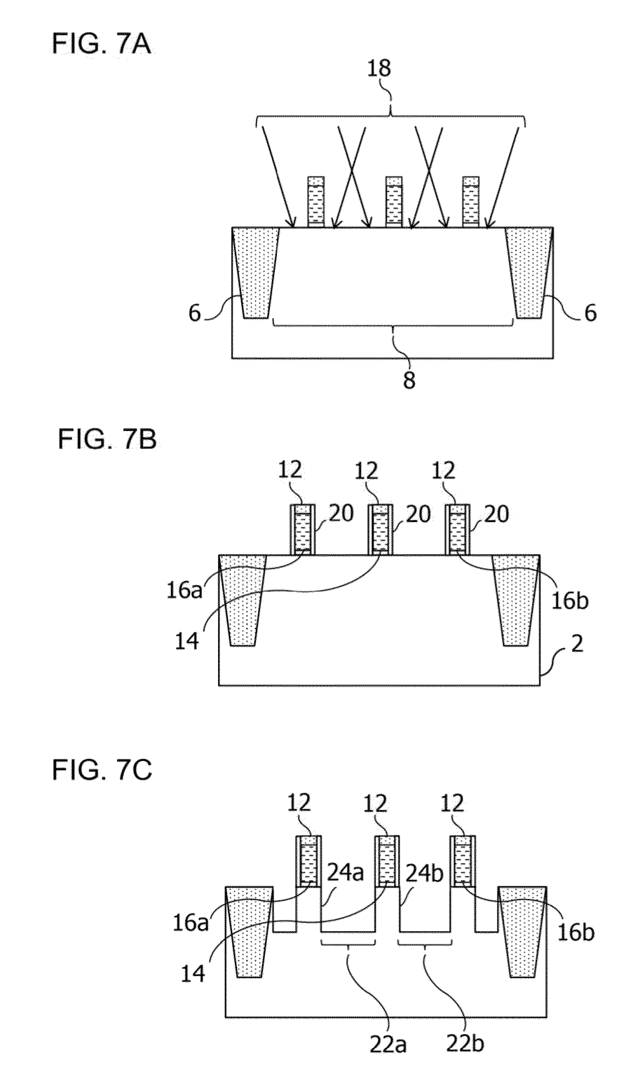

(1-4) Forming Process of Extension Region and Pocket Region (Refer to FIGS. 2A and 7A)

FIG. 2A is a plan view illustrating the forming process of an extension region and a pocket region. FIG. 7A is a section view along the VIIA-VIIA line depicted in FIG. 2A.

First, ions (not illustrated) of an n-type impurity (for example, As) are injected into the semiconductor region 8 (refer to FIG. 6C), wherein ion implantation depth is shallow (i.e. extension injection). Further, as depicted in

FIG. 7A, ions 18 of p-type impurity (for example, B) are injected into the semiconductor region 8, wherein ion implantation is obliquely performed (i.e. pocket injection).

Thereafter, heat treatment of the semiconductor region 8 (for example, spike anneal of 1000° C. or lower) is performed to activate the injected impurity and restore damage in the semiconductor region 8. Thus, an extension region (not illustrated) and a pocket region (not illustrated) are formed that suppress a short-channel effect.

Here, the extension injection and the pocket injection may be performed after forming an offset spacer on the side faces of the temporary gate electrode 14 etc. (refer to FIG. 6C) (this process is also applicable to embodiments 2 and 3). The offset spacer enables the adjustment of an amount of overlap between the extension region and the temporary gate electrode 14. The offset spacer may be formed by a deposition of SiN film and an etch back thereof, for example.

(1-5) Forming Process of Source/Drain Regions (Refer to FIGS. 2B-3A and FIGS. 7B-8A)

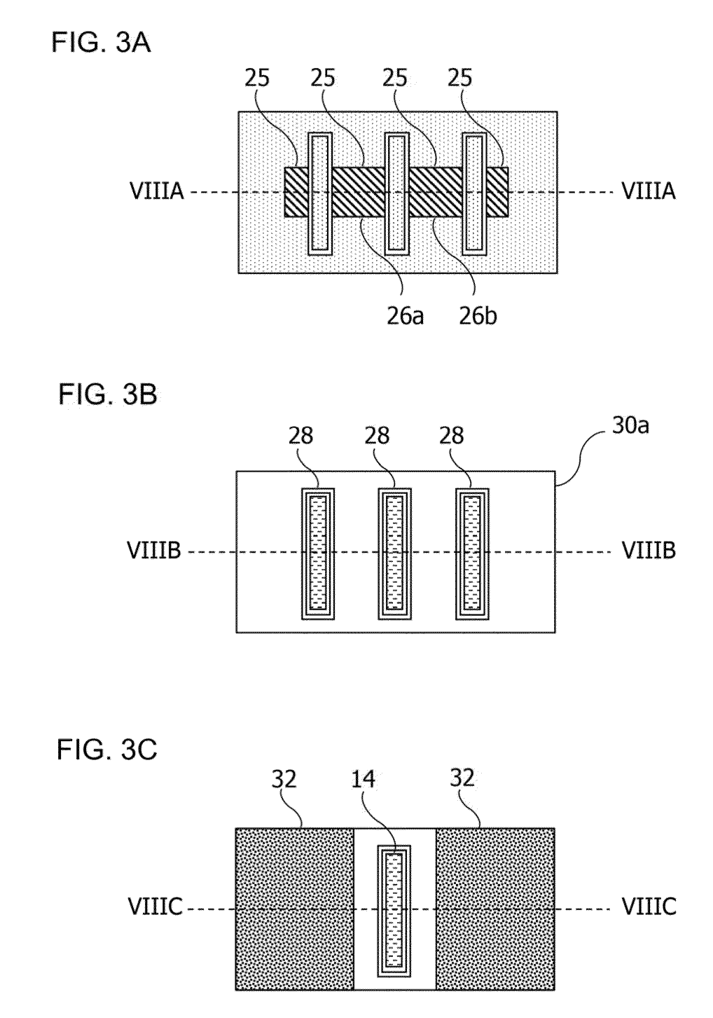

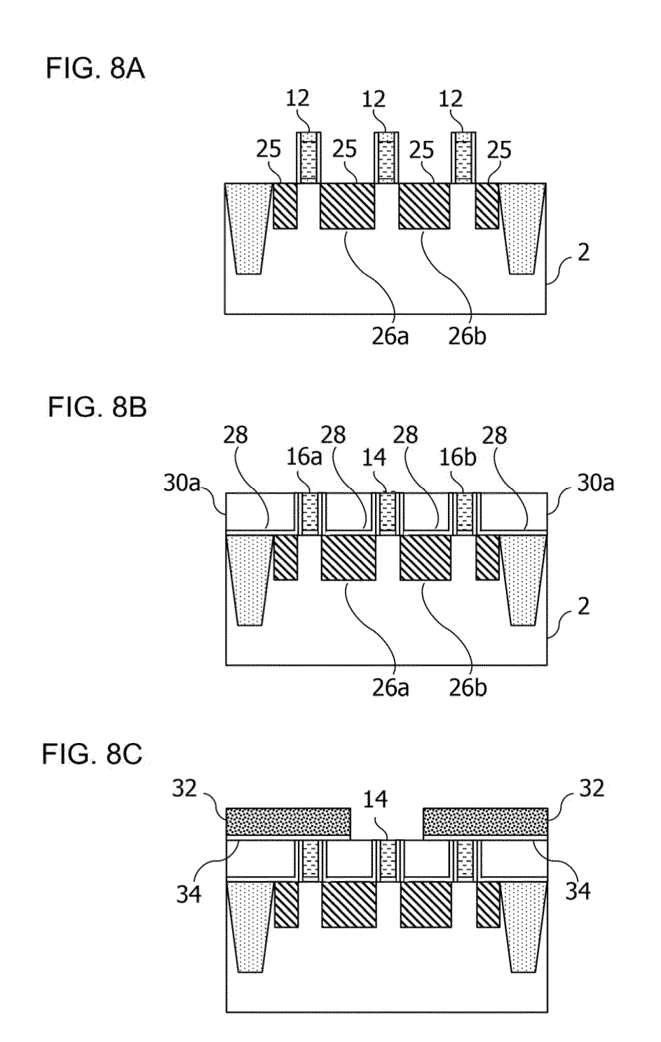

FIGS. 2B-3A are plan views illustrating a forming process of source/drain regions. FIG. 7B is a section view along the VIIB-VIIB line depicted in FIG. 2B. FIG. 7C is a section view along the VIIC-VIIC line depicted in FIG. 2C. FIG. 8A is a section view along the VIIIA-VIIIA line depicted in FIG. 3A.

—Forming Process of Recess—

First, as depicted in FIGS. 2B and 7B, sidewalls 20 are formed on the side faces of the temporary gate electrode 14, the first dummy gate electrode 16a, and the second dummy gate electrode 16b. The sidewalls 20 are formed by a deposition of a SiN film of, for example, 10 nm-20 nm in thickness and an etch back thereof.

Next, on the silicon substrate 2 on which the sidewalls 20 are formed, a SiO film (not illustrated) of 2 nm-5 nm in thickness and a SiN film (not illustrated) of 10 nm-40 nm in thickness are deposited in this order. Consequently, a stacked film (hereafter referred to as a SiO/SiN film) is formed. On the SiO/SiN film, formed is a resist pattern (i.e. a pattern of a photoresist film) that is provided with an aperture located on the semiconductor region 8. The SiO/SiN film is then etched through the resist pattern to form a hard mask (not illustrated).

Through the above hard mask and the hard masks 12 formed on the polysilicon film, the semiconductor region 8 is etched by, for example, dry-etching (or the combination of dry etching and wet etching). Consequently, as depicted in FIGS. 2C and 7C, a first recess 24a is provided in a first region 22a between the temporary gate electrode 14 and the first dummy gate electrode 16a in the semiconductor region 8. Further, a second recess 24b is provided in a second region 22b between the temporary gate electrode 14 and the second dummy gate electrode 16b in the semiconductor region 8. In other words, the second recess 24b is provided in the second region 22b on the second side of the temporary gate electrode 14 in the semiconductor region 8. Here, the second side (namely, the second dummy gate electrode 16b side) is different from the first side (the first dummy gate electrode 16a side).

Here, when the above-mentioned offset spacer has an appropriate thickness, it may also be possible to omit the forming of the sidewalls 20 (this process is also applicable to the embodiments 2 and 3).

—Forming Process of Semiconductor Layer (Source/Drain Region)—

Next, as depicted in FIGS. 3A and 8A, a silicon carbon 25 (that is, a mixed crystal of silicon and carbon) is epitaxially grown in the first recess 24a and the second recess 24b.

The silicon carbon (hereafter referred to as SiC) is grown by CVD from a mixed gas of trisilane (Si₃H₃) with monomethylsilane (CH₃SiH₃) as a source gas, for example. A deposition temperature is, for example, 500° C.-600° C. (preferably, 550° C.). Carbon composition in the SiC to be grown is, for example, 0.5-2.5 atomic percent. The carbon composition may be varied during the growth of SiC. Thereafter, the SiN film in the hard mask (the SiO/SiN film provided with the aperture on the semiconductor region 8) is removed.

Next, ions of an n-type impurity (for example, P or As) are injected into the SiC 25 grown in the first recess 24a and the SiC 25 grown in the second recess 24b. Thereafter, heat treatment of the semiconductor region 8 (for example, spike anneal of 1000° C. or lower) is performed to activate the injected impurity and restore damage in the SiC 25. After the heat treatment, the SiO film left on the hard mask (SiO/SiN film provided with the aperture on the semiconductor region 8) is removed.

Thus, as depicted in FIGS. 3A and 8A, a first semiconductor layer 26a (in the embodiment 1, SiC layer) with a second lattice constant smaller than the first lattice constant of the semiconductor region 8 is formed in the first recess 24a. Also, a second semiconductor layer 26b (in the embodiment 1, SiC layer) with a second lattice constant smaller than the first lattice constant of the semiconductor region 8 is formed in the second recess 24b. The first semiconductor layer 26a and the second semiconductor layer 26b become the source and drain regions of the strained channel NMOS transistor.

Here, instead of injecting ions of the n-type impurity into the first semiconductor layer 26a and the second semiconductor layer 26b, it may also be possible to epitaxially grow a semiconductor layer (in the embodiment 1, SiC layer) including an n-type impurity element (for example, P) using a source gas (for example, mixed gas of Si₃H₃ and CH₃SiH₃) to which a gas including an n-type impurity element (for example, PH₃) is added.

Now, the SiC may be grown also on the hard mask (SiO/SiN film provided with the aperture on the semiconductor region 8). In this case, the alternate repetition of the growth of SiC and the removal of SiC on the hard mask enables the forming of SiC layers in the first recess 24a and the second recess 24b. The SiC on the hard mask may be removed by exposing the SiC in a chlorine (Cl₂) gas and hydrogen (H₂) gas in a state in which the SiC is heated to 500° C.-600° C. (preferably, 550° C.).

(1-6) Removing Process of Temporary Gate Electrode (refer to FIGS. 3B-4A and FIGS. 8B-9A)

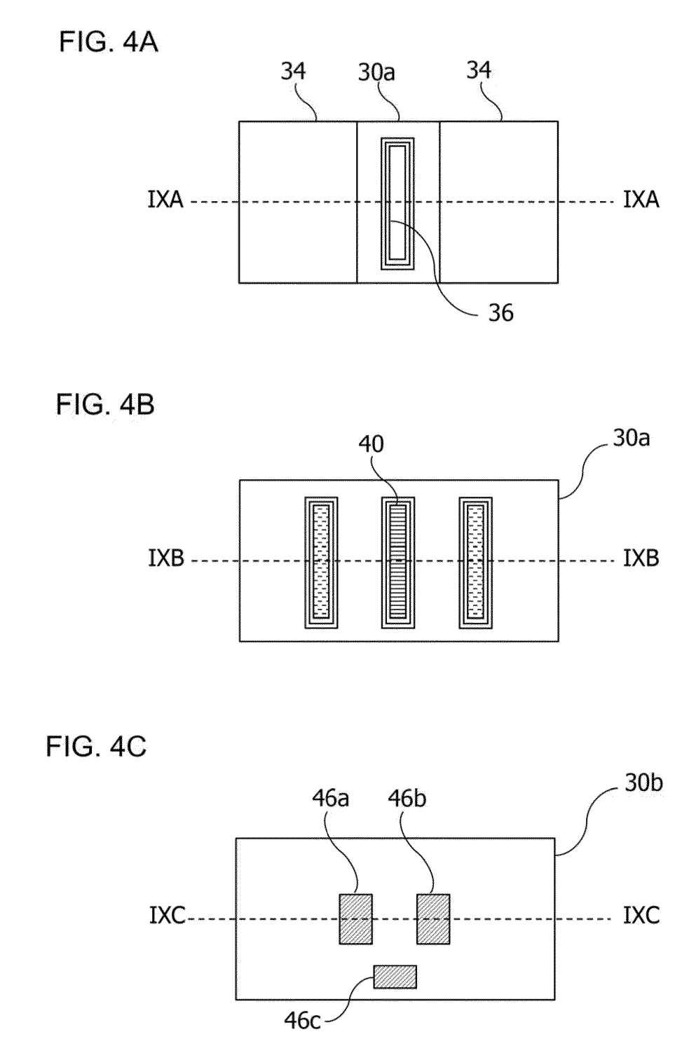

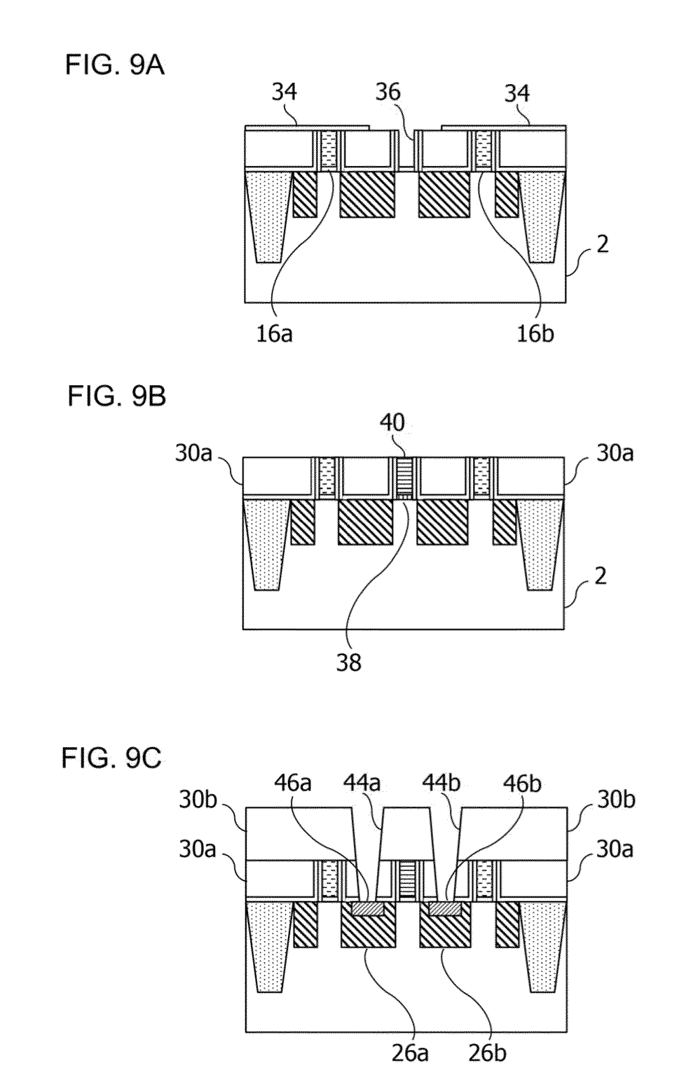

FIGS. 3B-4A are plan views illustrating the removing process of the temporary gate electrode 14. FIG. 8B is a section view along the VIIIB-VIIIB line depicted in FIG. 3B. FIG. 8C is a section view along the VIIIC-VIIIC line depicted in FIG. 3C. FIG. 9A is a section view along the IXA-IXA line depicted in FIG. 4A.

First, a SiN film of, for example, 10 nm-30 nm (preferably, 20 nm) in thickness is deposited on the Si substrate 2 (refer to FIG. 8A) on which the first semiconductor layer 26a and the second semiconductor layer 26b are formed. The SiN film becomes a CESL 28 (Contact Etch Stop Layer) (refer to FIG. 8B).

On the SiN film, a SiO film is deposited by, for example, HDP CVD (High-density Plasma Chemical Vapor Deposition) to bury the temporary gate electrode 14, the first dummy gate electrode 16a, and the second dummy gate electrode 16b. Thereafter, the SiO film and the SiN film are etched by CMP to expose the top face of the temporary gate electrode 14.

At this time, the hard mask 12 (refer to FIG. 8A) on the temporary gate electrode 14 is also etched. Further, the hard mask 12 on the first dummy gate electrode 16a and the hard mask 12 on the second dummy gate electrode 16b are removed also.

Thus, a first interlayer insulating film (interlayer dielectric) 30a and the CESL 28 are formed, as depicted in FIGS. 3B and 8B.

Next, on the Si substrate 2 on which the first interlayer insulating film 30a is formed, a SiN film of, for example, 20 nm-50 nm in thickness is deposited. The SiN film is etched through a resist pattern 32 (refer to FIGS. 3C and 8C) provided with an aperture on the temporary gate electrode 14, to form a hard mask 34 exposing the top face of the temporary gate electrode 14.

Next, through the hard mask 34, the temporary gate electrode 14 is etched as depicted in FIGS. 4A and 9A. The etching of the temporary gate electrode 14 is performed by dry etching or wet etching. It may also be possible to etch the temporary gate electrode 14 by the combination of dry etching with wet etching (this process is also applicable to embodiments 2 and 3).

Thus, the temporary gate electrode 14 is removed while the first dummy gate electrode 16a and the second dummy gate electrode 16b are left intact.

(1-7) Forming Process of Gate Insulating Film and Gate Electrode (Refer to FIGS. 4B and 9B)

FIGS. 4B is a plan view illustrating the forming process of a gate electrode. FIG. 9B is a section view along the IXB-IXB line depicted in FIG. 4B.

On the Si substrate 2 (refer to FIG. 9A) from which the temporary gate electrode 14 is removed, a high-dielectric-constant film (for example, a hafnium oxide film (hereafter referred to as a HfO film); not illustrated) of 1 nm-6 nm (preferably, 3 nm) in thickness is deposited, for example. Further, on the high-dielectric-constant film, a metal film (the metal film may be a single metal film, an alloy film, or a metallic compound film; not illustrated) is deposited so as to bury a region 36 (refer to FIG. 9A) from which the temporary gate electrode 14 is removed. Next, the first interlayer insulating film 30a and the metal film deposited on the hard mask 34 are removed by CMP. Thereafter, the hard mask 34 is removed by wet etching, for example.

Thus, as depicted in FIGS. 4B and 9B, a gate electrode 40 is formed in the region 36 from which the temporary gate electrode 14 is removed. Further, a gate insulating film 38 is formed between the gate electrode 40 and the semiconductor region 8. The gate insulating film 38 includes a part of the thermal oxide film formed on the Si substrate 2 and the high-dielectric-constant film (for example, HfO film). Here, the included part of the thermal oxide film 15 is located beneath the temporary gate electrode 14 (see FIG. 6C).

The metal film of the gate electrode 40 is, for example, Ti film, Ta film, TiN film, TaN film, etc. By appropriately selecting the material, the composition, the film thickness, etc. of the metal film, it is possible to adjust the threshold of the strained channel NMOS transistor (this adjustment is also applicable to a strained channel PMOS transistor according to an embodiment 2 and a FIN Field Effect Transistor according to an embodiment 3.)

Preferably, a metal film having low electric resistance, such as an Al film or a W film, is formed in the region 36 from which the temporary gate electrode 14 is removed (this process is also applicable to the embodiments 2 and 3). In this case, the gate electrode 40 includes a metal film for threshold adjustment (e.g. a TiN film) and a metal film for gate resistance reduction (e.g. Al). The high-dielectric-constant film may be a material other than HfO (for example, a zirconium oxide and an aluminum oxide).

(1-8) Forming Process of Contact and Wiring Layer (Refer to FIGS. 4C to 5 and FIGS. 9C to 10)

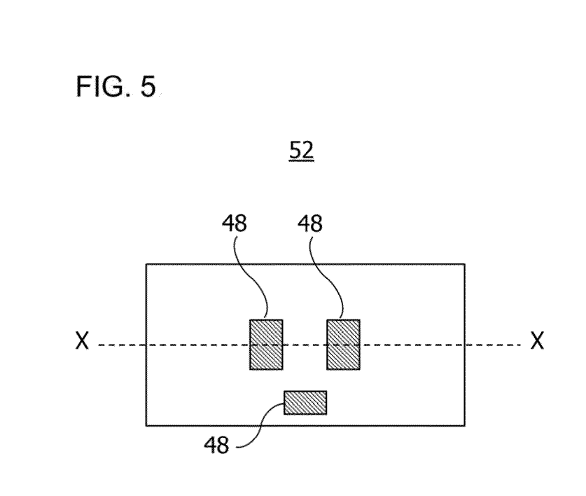

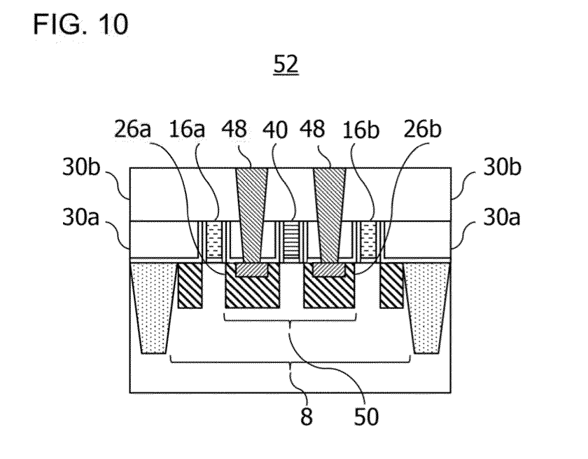

FIGS. 4C to 5 are plan views illustrating the forming process of a contact and a wiring layer. FIG. 9C is a section view along the IXC-IXC line depicted in FIG. 4C. FIG. 10 is a section view along the X-X line depicted in FIG. 5.

After the forming of the gate electrode 40, a second interlayer insulating film 30b is formed on the first interlayer insulating film 30a, as depicted in FIGS. 4C and 9C. Thereafter, the first interlayer insulating film 30a and the second interlayer insulating film 30b are etched through a resist pattern (not illustrated) and a hard mask (not illustrated). Thus, a first contact hole 44a reaching the first semiconductor layer 26a, a second contact hole 44b reaching the second semiconductor layer 26b, and a third contact hole (not illustrated) reaching the gate electrode 40 are formed as depicted in FIG. 9C.

A first contact electrode 46a (refer to FIG. 9C) is formed on the surface of the first semiconductor layer 26a exposed at the bottom of the first contact hole 44a (refer to FIG. 9C). Similarly, a second contact electrode 46b (refer to FIG. 9C) is formed on the surface of the second semiconductor layer 26b exposed at the bottom of the second contact hole 44b. Further, a third contact electrode 46c (refer to FIG. 4C) is formed on the surface of the gate electrode 40 exposed at the bottom of the third contact hole. The first contact electrode 46a and the second contact electrode 46b are silicide, for example.

Next, as depicted in FIGS. 5 and 10, vias 48 are formed on the first contact hole 44a to the third contact hole, respectively. For example, each via 48 includes a barrier metal film (for example, a TiN film) and a low-resistance metal (for example, W).

Thereafter, a wiring layer (not illustrated) including wiring (not illustrated) connected to the vias 48 is formed on the second interlayer insulating film 30b. Thus, a semiconductor device 52 including a strained channel NMOS transistor 50 is formed. The semiconductor device 52 may include a semiconductor device other than the strained channel NMOS transistor 50.

In the above-mentioned example, the high-dielectric-constant film is deposited on the thermal oxide film grown before the forming of the temporary gate electrode 14, so as to form the gate insulating film 38. However, the thermal oxide film may be removed after the removing of the temporary gate electrode 14. In this case, the surface of the semiconductor region 8, exposed by the removing of the thermal oxide film, is oxidized again to regrow a thermal oxide film. Thereafter, a high-dielectric-constant film is deposited on the regrown thermal oxide film, to form a gate insulating film (this process is also applicable to the embodiments 2 and 3).

The semiconductor device 52 may include a plurality of MOS Field

Effect Transistors (for example, strained channel NMOS transistors 50). In this case, the thickness of each thermal oxide film included in the gate insulating film 38 may not be the same. The thermal oxide film having a different thickness may be formed by repeating thermal oxidation of the semiconductor region 8 and partial removal of the formed thermal oxide film (this process is also applicable to the embodiments 2 and 3).

(2) Structure (Refer to FIGS. 5 and 10)

The semiconductor device 52 according to the embodiment 1 is a semiconductor device including the strained channel NMOS transistor 50.

As depicted in FIG. 10, the semiconductor device 52 includes the semiconductor region 8 (for example, a single crystal silicon region) having the first lattice constant, the gate electrode 40, the first dummy gate electrode 16a, and the second dummy gate electrode 16b.

The gate electrode 40 is disposed on the semiconductor region 8 and includes a first gate electrode material. The first gate electrode material is preferably a metal (the metal film may be a single metal film, an alloy film, or a metallic compound film). The first dummy gate electrode 16a is disposed on a first side of the gate electrode 40 on the semiconductor region 8 and includes a second gate electrode material (for example, polysilicon) different from the first gate electrode material.

The second dummy gate electrode 16b is disposed on a second side of the gate electrode 40 and includes a second gate electrode material. Here, the second side is different from the first side.

The semiconductor device 52 further includes the first semiconductor layer 26a and the second semiconductor layer 26b. The first semiconductor layer 26a is disposed in the first recess 24a (refer to FIG. 7C) provided in a first region between the first dummy gate electrode 16a and the gate electrode 40 in the semiconductor region 8 and has the second lattice constant smaller than the first lattice constant. In contrast, the second semiconductor layer 26b has the second lattice constant, and is disposed in the second recess 24b (refer to FIG. 7C) provided in a second region between the second dummy gate electrode 16b and the gate electrode 40 in the semiconductor region 8.

Here, the first semiconductor layer 26a and the second semiconductor layer 26b are made of a semiconductor (for example, SiC) formed by epitaxial growth. The direction from the first semiconductor layer 26a toward the second semiconductor layer 26b is preferably the [011] direction of a single crystal that forms the semiconductor region 8.

(3) Strain Increase in Channel Region Due to Temporary Gate Removing

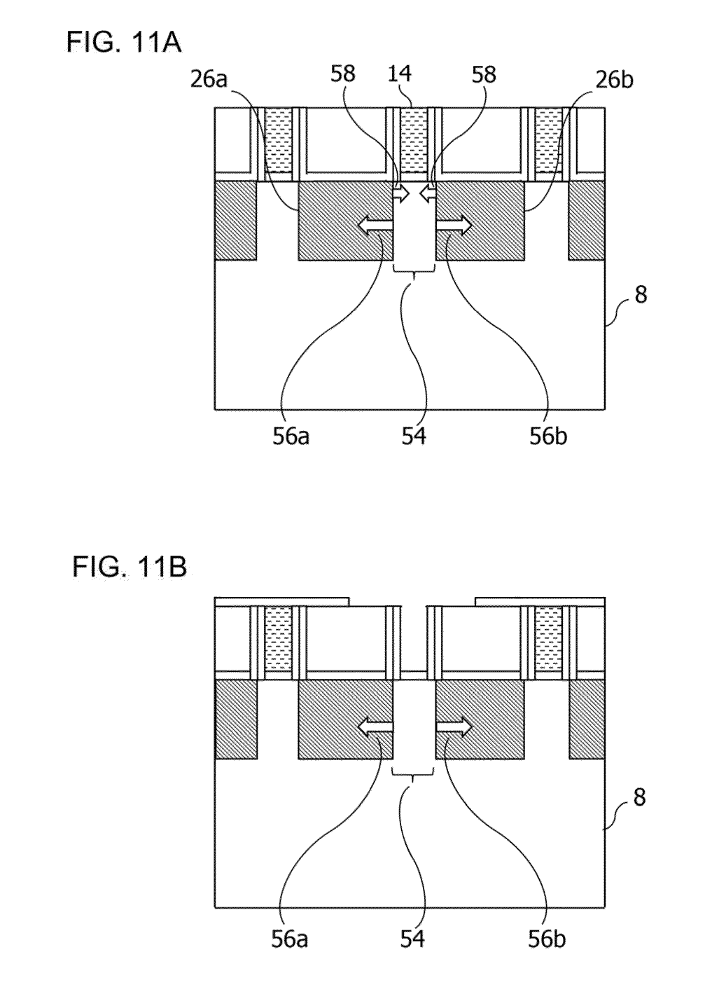

FIG. 11A is a diagram illustrating the states of a channel region 54 before the temporary gate electrode 14 is removed.

According to the embodiment 1, the first semiconductor layer 26a (for example, SiC) having a smaller lattice constant than the semiconductor region 8 (for example, a Si region) is epitaxially grown in the first recess 24a. Similarly, the second semiconductor layer 26b (for example, SiC) having a smaller lattice constant than the semiconductor region 8 (for example, a Si region) is epitaxially grown in the second recess 24b.

Then, the channel region 54 receives a tensile stress 56a from the first semiconductor layer 26a. The reason is that the lattice constant of the first semiconductor layer 26a is smaller than the lattice constant of the semiconductor region 8. By the tensile stress 56a, the channel region 54 is stretched toward the first semiconductor layer 26a. Similarly, by a tensile stress 56b from the second semiconductor layer 26b, the channel region 54 is stretched toward the second semiconductor layer 26b. Thus, a tensile strain is produced in the channel region 54.

At this time, the channel region 54 exerts on the temporary gate electrode 14 a stress (not illustrated) to stretch the temporary gate electrode 14 to a direction parallel to the semiconductor region 8. By a reaction 58 to the stress, the tensile strain in the channel region 54 is suppressed.

FIG. 11B is a diagram illustrating the state of the channel region 54 after the removing of the temporary gate electrode 14. When the temporary gate electrode 14 is removed, the reaction 58 (refer to FIG. 11A) from the temporary gate electrode 14 disappears, as depicted in FIG. 11B. As a result, the tensile strain is increased in the channel region 54. The increased tensile strain is preserved when the gate electrode 40 is formed thereafter in a region from which the temporary gate electrode 14 is removed.

According to the embodiment 1, the temporary gate electrode 14 is removed while the first dummy gate electrode 16a and the second dummy gate electrode 16b are left intact. However, it may also be considered that the temporary gate electrode 14 is removed together with the first dummy gate electrode 16a and the second dummy gate electrode 16b.

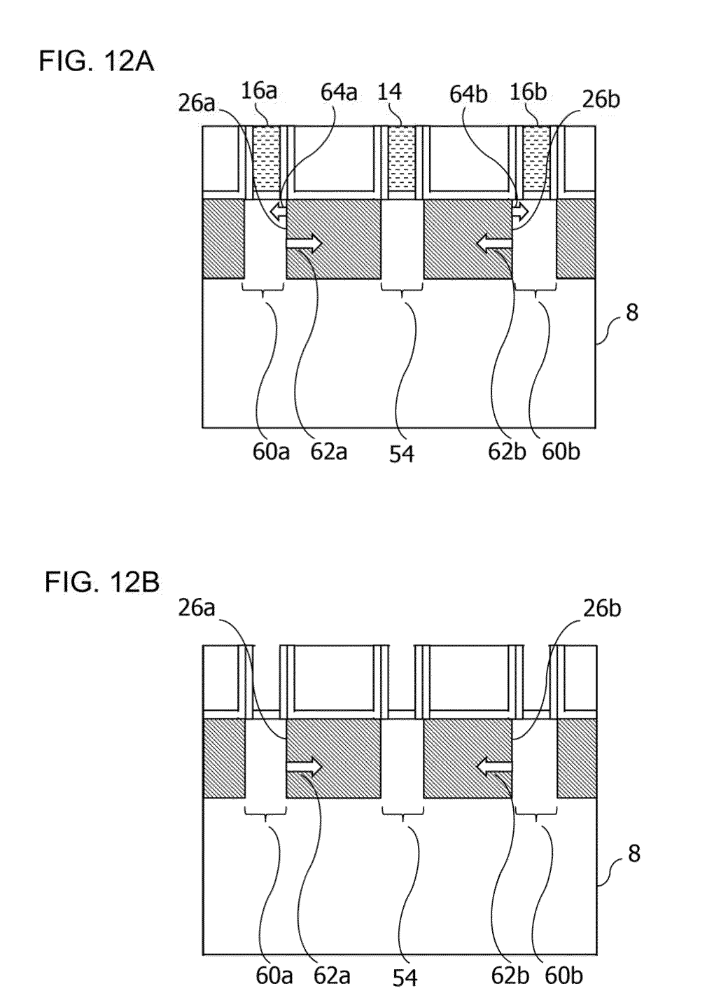

FIG. 12A is a diagram illustrating the state of the channel region 54 before the temporary gate electrode 14 is removed together with the first dummy gate electrode 16a and the second dummy gate electrode 16b. FIG. 12B is a diagram illustrating the state of the channel region 54 after the temporary gate electrode 14 is removed together with the first dummy gate electrode 16a and the second dummy gate electrode 16b.

As depicted in FIG. 12A, a region 60a beneath the first dummy gate electrode 16a receives both a tensile stress 62a from the first semiconductor layer 26a and a reaction 64a from the first dummy gate electrode 16a. Similarly, a region 60b beneath the second dummy gate electrode 16b receives a tensile stress 62b from the second semiconductor layer 26b and a reaction 64b from the second dummy gate electrode 16b. In FIG. 12A, stresses that the channel region 54 receives is omitted.

When the first dummy gate electrode 16a is removed, the reaction 64a from the first dummy gate electrode 16a disappears as depicted in FIG. 12B, resulting in a stretch in the region 60a beneath the first dummy gate electrode 16a. As a result, a strain in the first semiconductor layer 26a generated by lattice mismatch between the first semiconductor layer 26a and the semiconductor region 8 is reduced. Therefore, the tensile stress 56a (refer to FIG. 11A) that the first semiconductor layer 26a exerts on the channel region 54 becomes smaller than that obtained when only the temporary gate electrode 14 is removed.

Similarly, the tensile stress 56b (refer to FIG. 11A) that the second semiconductor layer 26b exerts on the channel region 54 becomes smaller than that obtained when only the temporary gate electrode 14 is removed.

As a result, the tensile stress in the channel region 54 becomes smaller as compared to the case in which only the temporary gate electrode 14 is removed. In other words, by the removing of only the temporary gate electrode 14, it is possible to concentrate into the channel region 54 a strain increase in the semiconductor region 8. Here, the strain increase is caused by the removing of gate electrodes (gate-shaped electrodes such as the temporary gate electrode 14 and the dummy gate electrodes 16a, 16b).

Thus, electron mobility in the channel region 54 becomes larger than the electron mobility obtained when the temporary gate electrode 14 is removed together with the first dummy gate electrode 16a and the second dummy gate electrode 16b.

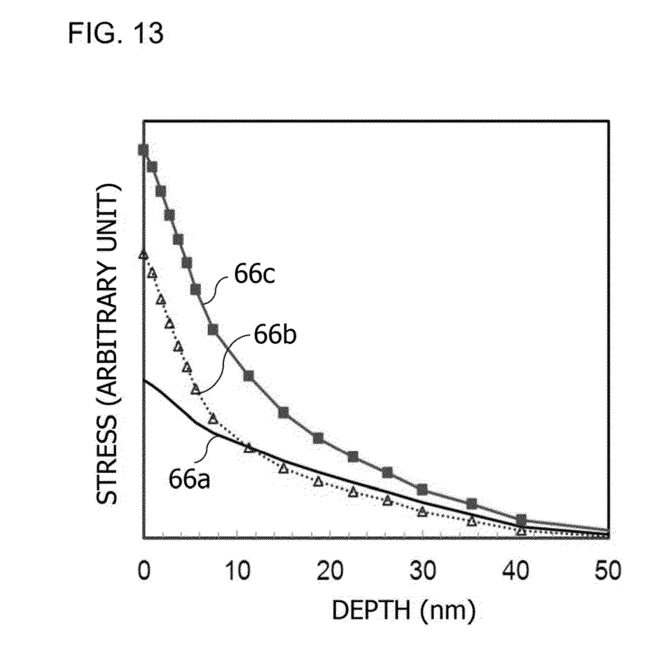

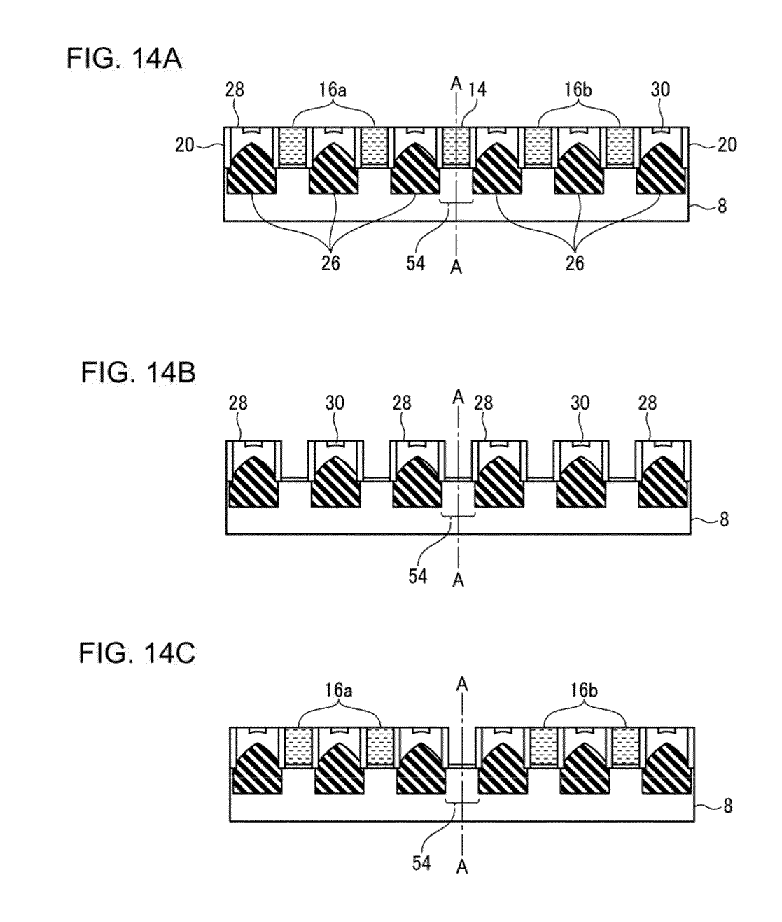

FIG. 13 is a diagram illustrating the calculated values of tensile stresses (the sum of tensile stresses) applied to the channel region 54. FIGS. 14A-14C are section views illustrating models used for the calculation of FIG. 13.

FIG. 14A illustrates a semiconductor device model of the embodiment 1 before the removing of the temporary gate electrode 14 and the dummy gate electrodes 16a, 16b. FIG. 14B illustrates a model in which the temporary gate electrode 14 and the dummy gate electrodes 16a, 16b are removed. FIG. 14C illustrates a model in which only the temporary gate electrode 14 is removed.

Each model depicted in FIGS. 14A-14C includes two first dummy gate electrodes 16a (polysilicon) disposed on the first side of the temporary gate electrode 14 and two second dummy gate electrodes 16b (polysilicon) disposed on the second side of the temporary gate electrode 14. In the models depicted in FIGS. 14A-14C, the interlayer insulating film 30 is almost removed by CMP, and there is only a little film left on the surface of the CESL 28. The interlayer insulating film 30 hardly influences the calculation values depicted in FIG. 13.

Each length (gate length) of the temporary gate electrode 14 and the dummy gate electrodes 16a, 16b is 20 nm. The period (gate pitch) of a gate electrode group including the temporary gate electrode 14 and the dummy gate electrodes 16a, 16b is 62 nm. Each height of the temporary gate electrode 14 and the dummy gate electrodes 16a, 16b is 30 nm. The thickness of the sidewall 20 (SiN film) is 5 nm. The depth of the recess provided in the semiconductor region 8 (Si region) is 20 nm. The semiconductor layer 26 provided in the recess is SiC in which carbon composition is 2 atomic percent.

The vertical axis depicted in FIG. 13 represents a tensile stress in the channel region 54 along the A-A line depicted in FIGS. 14A-14C. The horizontal axis represents a depth of the channel region 54 from the surface.

The first line 66a depicted in FIG. 13 represents a tensile stress in the channel region 54 before the removing of the temporary gate electrode 14 and/or the dummy gate electrodes 16a, 16b (refer to FIG. 14A). The second line 66b depicted in FIG. 13 represents a tensile stress obtained in the channel region 54 when the temporary gate electrode 14 and the dummy gate electrodes 16a, 16b are removed (refer to FIG. 14B). The third line 66c depicted in FIG. 13 represents a tensile stress obtained in the channel region 54 when only the temporary gate electrode 14 is removed (refer to FIG. 14C).

As depicted in FIG. 13, when the temporary gate electrode 14 and the dummy gate electrodes 16a, 16b are removed, the tensile stress (refer to the second line 66b) in the channel region 54 becomes larger than the tensile stress (refer to the first line 66a) before the removing. When only the temporary gate electrode 14 is removed, the tensile stress (refer to the third line 66c) in the channel region 54 becomes larger than the tensile stress obtained when the temporary gate electrode 14 and the dummy gate electrodes 16a, 16b are removed together (refer to the second line 66b).

This is because a strain increase of the semiconductor region 8 (a strain increase due to the removing of the gate-shaped electrode) is concentrated in the channel region 54, when only the temporary gate electrode 14 is removed, as described above.

### Reference Example

A technique to form SiGe layers on both sides of a channel region for improving carrier mobility is already put into practice. For this technique, important is the technique in which a gate electrode is once removed and is formed again thereafter, as a technique to improve the mobility of a strained channel MOS Field Effect Transistor (MOS Field Effect Transistor in which a strain is introduced in a channel region).

Now, when a MOS Field Effect Transistor is made fine, the size of a resist film (hereafter referred to as a gate electrode pattern) for use to form a gate electrode is easily varied due to the variation of a resist pattern density (so-called an optical proximity effect). To cope with this problem, a size variation of the gate electrode pattern due to the optical proximity effect is suppressed by forming of a plurality of gate electrode patterns that have a certain size and extend to a certain direction, with a certain pitch.

When a MOS Field Effect Transistor is formed by the above method, a gate electrode is formed on one side of a source/drain region, while an electrode (hereafter referred to as a dummy gate electrode) that is not used as the gate electrode of the MOS Field Effect Transistor is formed on another side of the source/drain region.

When source/drain regions including a SiGe layer are formed on both sides (that is, both sides of the gate electrode) of the channel region using the above method in which the dummy gate electrode is formed, SiGe layers sandwiched between the gate electrode and the dummy gate electrode are formed.

When the dummy gate electrode is removed from the above structure together with the gate electrode, as described by reference to FIGS. 12A-12B, the SiGe layers expand to both the gate electrode side and the dummy gate electrode side. The expansion of the SiGe layers to the gate electrode side causes a strain increase in a channel region. Meanwhile, the expansion of the SiGe layers to the dummy gate electrode side causes a strain increase in a semiconductor layer beneath the dummy gate electrode.

However, the expansion of the SiGe layers to the dummy gate electrode side only increases the strain in the semiconductor layer beneath the dummy gate electrode and does not increase the strain in the channel region (semiconductor layer beneath the gate electrode).

As seen above, in the technique of removing the gate electrode and the dummy gate electrode, there is a problem that a strain increase caused by the expansion of the SiGe layers is spread into the channel region and the semiconductor layer beneath the dummy gate electrode.

(4) Operation

The semiconductor device 52 (refer to FIG. 10) includes a MIS (metal-insulator-semiconductor) Field Effect Transistor. The strained channel

NMOS transistor 50 is one of MIS Field Effect Transistors included in the semiconductor device 52.

The first semiconductor layer 26a is one of source/drain regions of the strained channel NMOS transistor 50. The second semiconductor layer 26b is another source/drain region of the strained channel NMOS transistor 50.

A voltage higher than a threshold voltage is applied to the gate electrode 40 while a voltage is applied between the first semiconductor layer 26a and the second semiconductor layer 26b. Then, the strained channel NMOS transistor 50 becomes an ON state and generates a current flow in a channel region sandwiched between the first semiconductor layer 26a and the second semiconductor layer 26b.

On the other hand, when a voltage lower than the threshold is applied to the gate electrode 40 and a voltage is applied between the first semiconductor layer 26a and the second semiconductor layer 26b, the strained channel NMOS transistor 50 becomes an OFF state and generates no current flow in the channel region 54.

According to the embodiment 1, the characteristic (for example, current in a linear region and a saturation region) of the strained channel NMOS transistor 50 is improved because of increased mobility in the channel region 54.

(5) Modified Example

According to the embodiment 1, the whole first dummy gate electrode 16a is formed on the semiconductor region 8. However, the first dummy gate electrode 16a may also be provided in such a way as to extend across a boundary between the semiconductor region 8 and the STI region 6 (refer to FIG. 7A). Namely, according to the embodiment 1, at least a part of the first dummy gate electrode 16a is formed on the semiconductor region 8. The same is also applicable to the second dummy gate electrode 16b.

### Embodiment 2

An embodiment 2 resembles the embodiment 1. Therefore, the description of each part common to the embodiment 1 will be omitted or simplified.

According to the embodiment 2, the lattice constant (that is, the second lattice constant) of the first semiconductor layer 26a (refer to FIG. 10) and the second semiconductor layer 26b is larger than the lattice constant (that is, the first lattice constant) of the semiconductor region 8. Also, the MOS Field Effect Transistor formed in the semiconductor region 8 is a p-type MOS Field Effect Transistor (hereafter referred to as a strained channel PMOS transistor) having a strain in the channel region.

The semiconductor region 8 is formed of a Si substrate, for example. The material of the first semiconductor layer 26a and the second semiconductor layer 26b is SiGe, for example.

The semiconductor device according to the embodiment 2 is manufactured by substantially the same processes as the manufacturing method in the embodiment 1. However, in the following point, the manufacturing method according to the second embodiment is different from the manufacturing method according to the first embodiment.

First, in the “(1-2) Forming process of active region (refer to FIGS. 1B and 6B)” (refer to the embodiment 1), ions of an n-type impurity (for example, P) are injected into the semiconductor region 8.

Also, in the “(1-4) Forming process of extension region and pocket region (refer to FIGS. 2A and 7A)” (refer to the embodiment 1), ions of a p-type impurity (for example, B) are injected into the region corresponding to the extension region. Further, ions of an n-type impurity (for example, As) are injected into the region corresponding to the pocket region.

In the “(1-5) Forming process of source/drain region (refer to FIGS. 2B-3A and FIGS. 7B-8A)” (refer to the embodiment 1), SiGe is epitaxially grown in the first recess 24a and the second recess 24b. SiGe is grown by CVD using a mixed gas of silane (SiH₄), chlorine (HCl) and germane (GeH₄) as a source gas. A deposition temperature is 600° C.-700° C., for example (preferably 650° C.). The Ge composition of SiGe is 20-40 atomic percent, for example. The Ge composition may be varied during the grow of SiGe.

Next, ions of a p-type impurity (for example, B) are injected into the first semiconductor layer 26a and the second semiconductor layer 26b.

Thereafter, the semiconductor region 8 is heat-treated to activate the injected impurity. Instead of injecting ions of the p-type impurity, it may also be possible to epitaxially grow a semiconductor layer including a p-type impurity element (for example, B) as the first semiconductor layer 26a and the second semiconductor layer 26b, using a source gas (mixed gas of SiH₄, HCl and GeH₄) to which a gas including a p-type impurity element (for example, B₂H₆ gas) is added.

In the “(1-7) Forming process of gate insulating film and gate electrode (refer to FIGS. 4B and 9B)” (refer to the embodiment 1), the gate electrode 40 is formed using a material corresponding to a threshold target value of the strained channel PMOS transistor.

According to the embodiment 2, a compression strain is generated in the channel region. This produces larger mobility of a positive hole in the channel region than that obtained when the temporary gate electrode 14 is removed together with the first dummy gate electrode 16a and the second dummy gate electrode 16b.

Additionally, it may also be possible to form both the strained channel PMOS transistor of the embodiment 2 and the strained channel NMOS transistor of the embodiment 1 on the same substrate.

### Embodiment 3

An embodiment 3 resembles the embodiment 1. Therefore, the description of each part common to the embodiment 1 will be omitted or simplified.

A semiconductor device according to the embodiment 3 includes a strained channel NMOS transistor provided in a convex semiconductor region that extends to one direction. The semiconductor device according to the embodiment 3 also includes a strained channel PMOS transistor provided in the above semiconductor region.

(1) Manufacturing Method

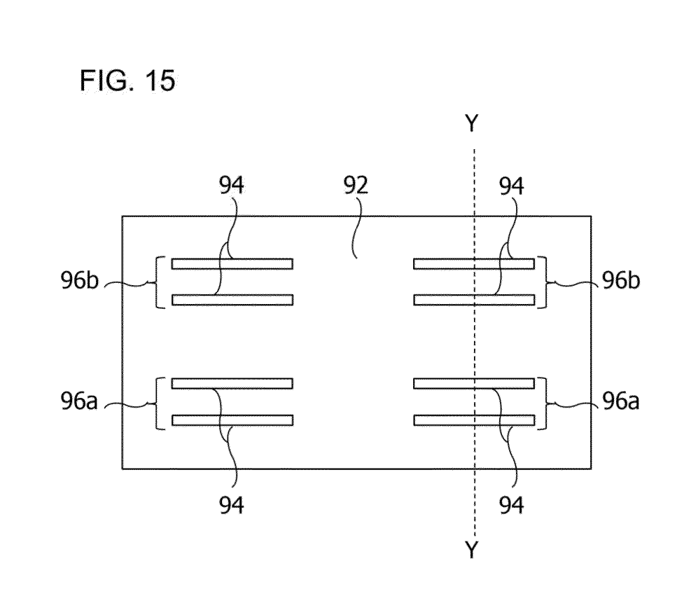

FIGS. 15-32 are diagrams illustrating a manufacturing method for the semiconductor device according to the embodiment 3.

(1-1) Forming Process of Fin (Refer to FIGS. 15-18)

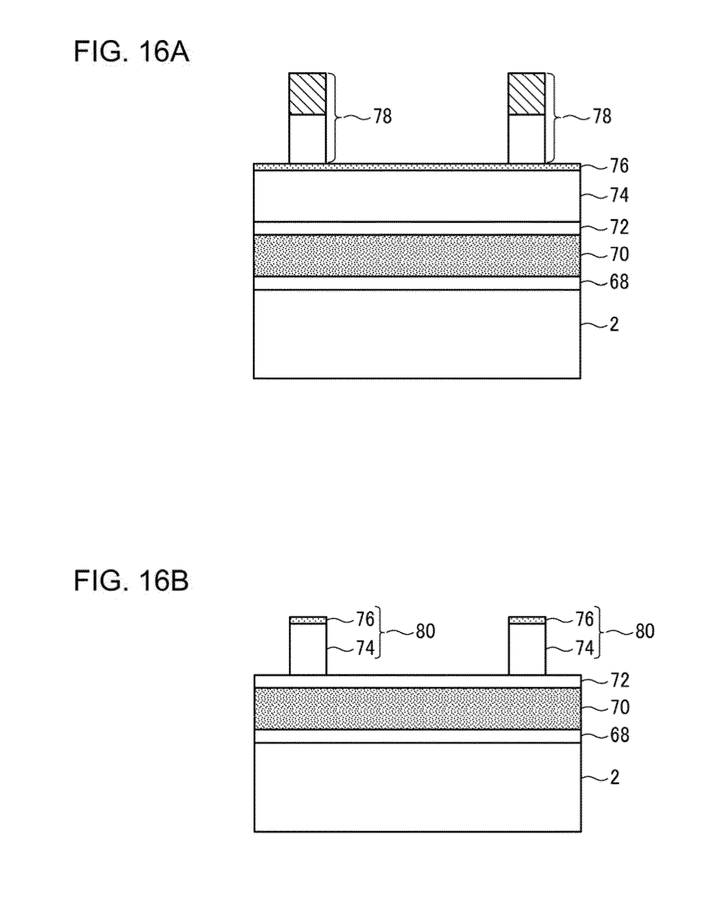

First, as depicted in FIG. 15, a plurality of fin-shaped semiconductor regions 94 (hereafter referred to as Fins) are formed in a first transistor region 96a and a second transistor region 96b, respectively, on a Si substrate 2. FIGS. 16A-18C are section views illustrating the forming process of the Fins 94 along the Y-Y line depicted in FIG. 15.

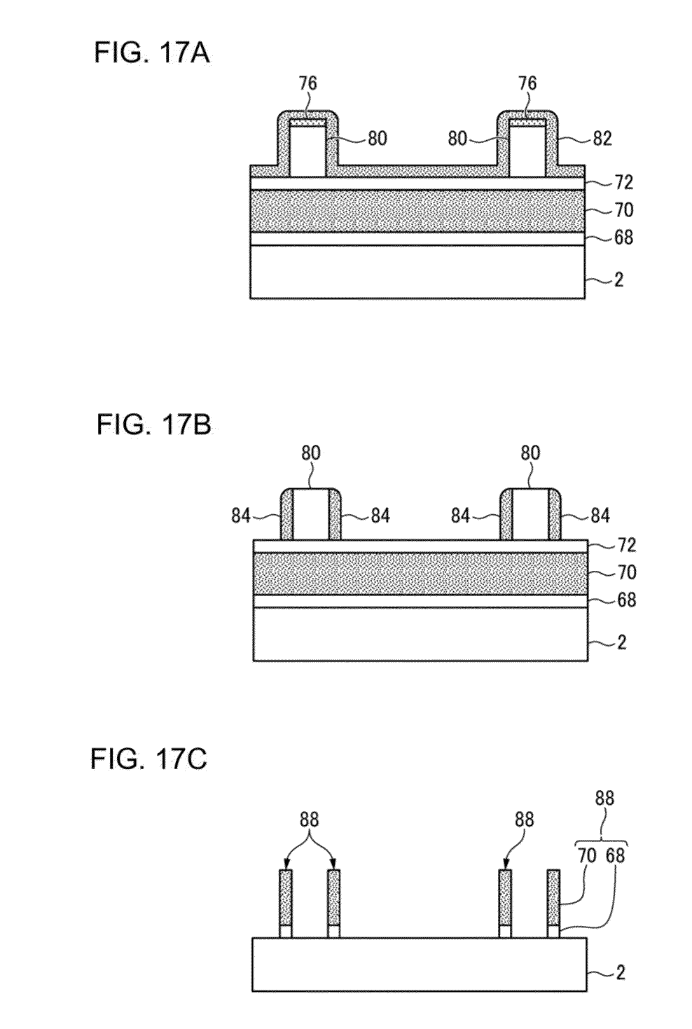

—Forming of Fin Hard Mask (Refer to FIGS. 16A-17C)—

FIGS. 16A-17C are section views illustrating the forming process of hard masks corresponding to Fins 94.

First, a thermal oxide film 68 of 2 nm-10 nm (preferably 5 nm) in thickness is grown on the Si substrate 2. Further, on the thermal oxide film 68, a SiN film 70 of 25 nm-100 nm (preferably 50 nm) in thickness is grown by LP-CVD and the like. Further, on the SiN film 70, a SiO₂ film 72 of 5 nm-20 nm (preferably 10 nm) in thickness is grown by CVD. Further, on the SiO₂ film 72, a carbon film 74 of 100 nm-150 nm in thickness is grown by CVD. Further, on the carbon film 74, a SiN film 76 is grown by plasma CVD. The SiN film 76 is an antireflection film. The plane orientation of the Si substrate 2 is preferably (100).

Next, on the antireflection film 76, resist patterns 78 (patterns of photoresist film) corresponding to cores, which will be described later, are formed by immersion ArF lithography, for example. In this case, preferably, the thickness of the SiN film 76 (antireflection film) is approximately 30 nm. The pitch of the resist patterns 78 is, for example, 45 nm-180 nm (preferably, 90 nm).

Through the resist patterns 78, the SiN film 76 and the carbon film 74 are dry-etched by RIE, so that cores 80 of hard masks corresponding to the Fins are formed as depicted in FIG. 16B. In the above RIE, for example, plasma is generated from a gas including O₂ gas to irradiate the SiN film 76 and the carbon film 74 therewith. By the above RIE, the resist patterns 78 are extinguished.

Next, as depicted in FIG. 17A, on the Si substrate 2 on which the cores 80 are formed, a SiN film 82 of 5 nm-20 nm (preferably, 10 nm) in thickness is deposited by plasma CVD, for example. Then, the SiN film 82 is etched using anisotropic etching (for example, RIE) to form each spacer 84 on each side face of the cores 80, as depicted in FIG. 17B. By the above RIE, the SiN film 76 (antireflection film) on the top faces of the cores 80 is removed. Next, a part of the spacers 84 is removed. Here, the removed part is not corresponding to the Fin (for example, a spacer formed on each side face of the both ends of core 80).

Next, the cores 80 are removed by RIE. Thereafter, the SiO₂ film 72, the SiN film 70, and the thermal oxide film 68 are etched by RIE, so that hard masks 88 (hereafter referred to as Fin hard masks) corresponding to the Fins are formed, as depicted in FIG. 17C. By the above RIE, the spacers 84 and the SiO₂ film 72 just below the spacers 84 are removed.

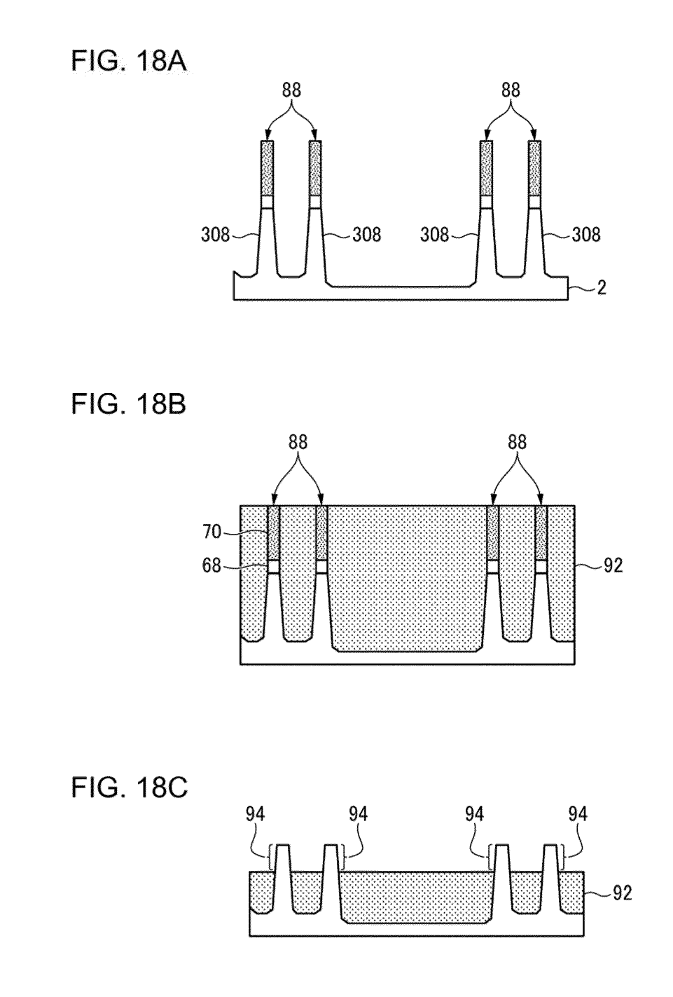

—Etching and Burying (Refer to FIGS. 18A-18C)—

FIGS. 18A-18C are section views illustrating a forming process of Fins using the Fin hard masks 88.

First, as depicted in FIG. 18A, the Si substrate 2 is dry-etched to the depth of 80 nm-120 nm through the hard masks 88, to form each convex semiconductor regions 308. Further, a plasma oxide film is deposited on the Si substrate 2 from which the convex semiconductor regions 308 are formed.

Next, as depicted in FIG. 18B, the above plasma oxide film 92 is polished by CMP until the Fin hard masks 88 are exposed.

Next, a part of the Fin hard mask 88 is removed by wet etching. Here, the removed part of the Fin hard mask 88 is formed from the SiN film 70. Further, the upper part of the plasma oxide film 92 is removed by wet etching, so that a fin-shaped protrusion 94 (that is, Fin) is formed as depicted in FIG. 18C. At this time, a part of the hard mask 88 is removed. Here, the removed part of the hard mask 88 is formed from the thermal oxide film 68. The width of the Fin 94 is 10 nm or smaller (preferably, 2 nm or greater), for example. The height of the Fin is 15 nm-60 nm (preferably, 30 nm).

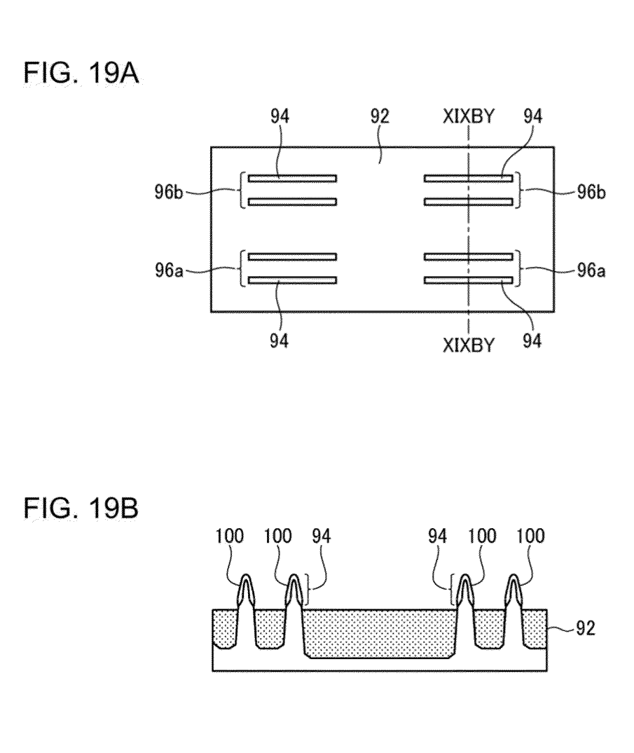

(1-2) Forming Process of Active Region (Refer to FIGS. 19A and 19B)

FIG. 19A is a plan view illustrating a forming process of an active regions. FIG. 19B is a section view along the XIXBY-XIXBY line depicted in FIG. 19A.

First, the surfaces of the Fins 94 are oxidized to grow a sacrificial oxide film 100 (refer to FIG. 19B) of 2 nm-10 nm (preferably, 5 nm) in thickness. Thereafter, ions of a p-type impurity (for example, B) are injected into the first transistor region 96a through a resist pattern (not illustrated) provides with an aperture on the first transistor region 96a. Further, ions of an n-type impurity (for example, P) are injected into the second transistor region 96b through a resist pattern (not illustrated) provided with an aperture on the second transistor region 96b.

Next, heat treatment (for example, Rapid Thermal Anneal) of the first transistor region 96a and the second transistor region 96b is performed, so that the injected impurity is activated and also damage in Fins 94 are restored. Consequently, the Fins of the first transistor region 96a become p-type active regions. Also, the Fins of the second transistor regions 96b become n-type active regions.

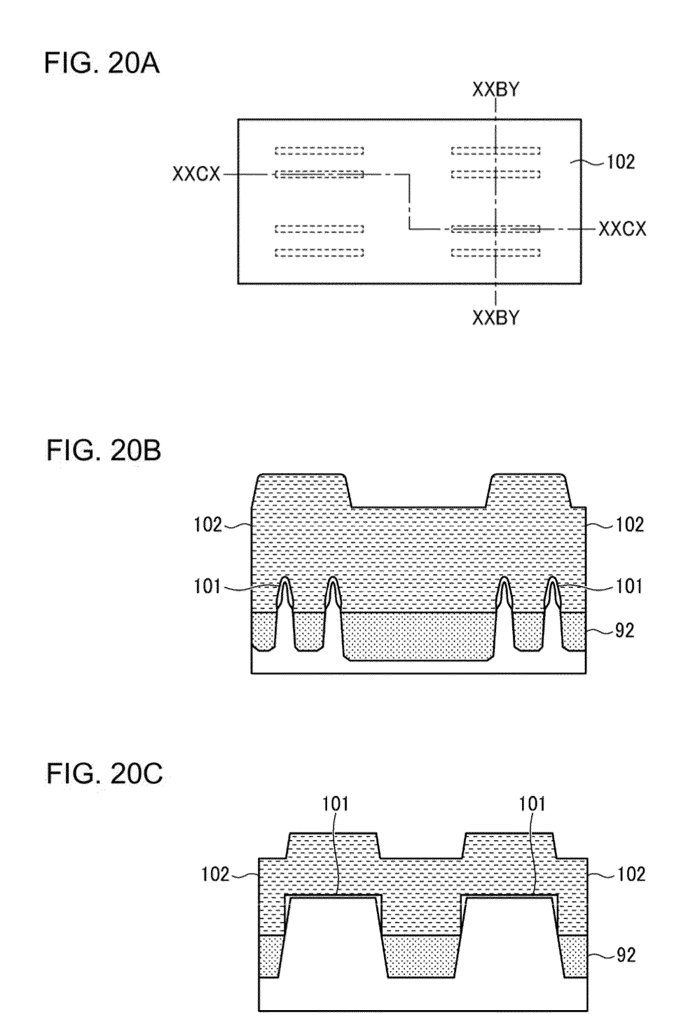

(1-3) Forming Process of Temporary Gate Electrode and Dummy Gate Electrode (Refer to FIGS. 20A-22C)

FIGS. 20A-22C are diagrams illustrating the forming process of the temporary gate electrodes and the dummy gate electrodes. FIG. 20A is a plan view illustrating the forming process of the temporary gate electrodes and the dummy gate electrodes. FIG. 20B is a section view along the XXBY-XXBY line depicted in FIG. 20A. FIG. 20C is a section view along the XXCX-XXCX line depicted in FIG. 20A.

First, the sacrificial oxide film 100 is removed by wet etching. Thereafter, the surfaces of the Fins 94 are oxidized for 1 nm-3 nm, for example, to form thermal oxide films 101. Each of the thermal oxide films 101 becomes a part of gate insulating film described later.

On the oxide films 101 and the plasma oxide film 92, a polysilicon film 102 of, for example, 50 nm-200 nm (preferably, 100 nm) in thickness is formed by CVD (refer to FIGS. 20B and 20C). It may also be possible to form an amorphous silicon film in place of the polysilicon film.

The polysilicon film 102 is polished by CMP to flatten the surface of the polysilicon film 102, for example. Here, polishing amount is 10 nm-30 nm in thickness, for example. This enables easy forming of resist patterns on the polysilicon film 102.

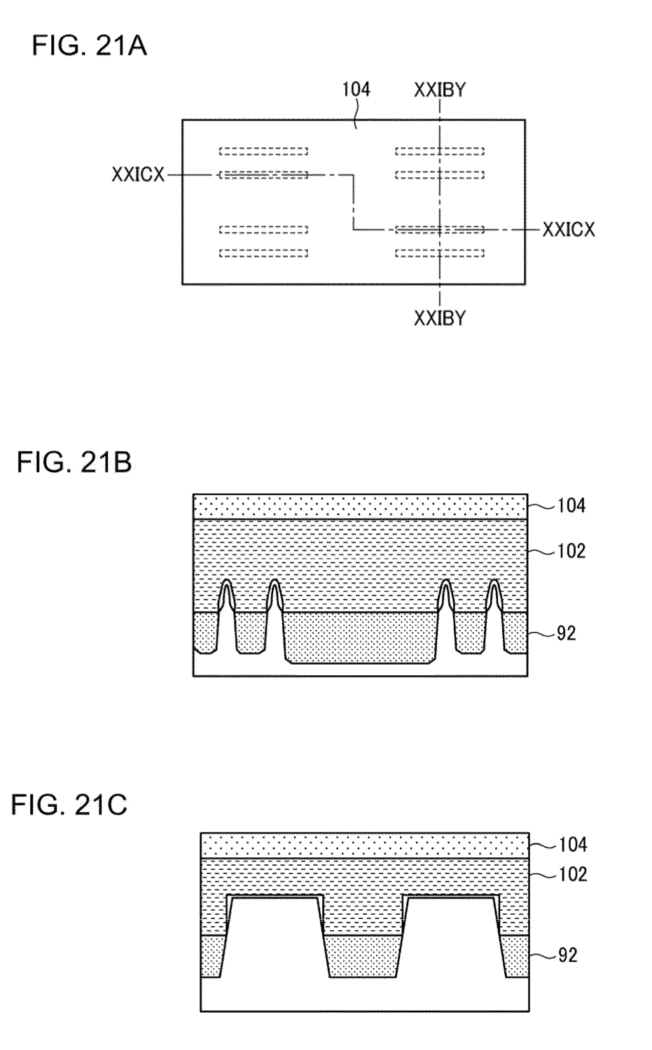

FIG. 21A is a plan view illustrating the forming process of the temporary gate electrodes and the dummy gate electrodes. FIG. 21B is a section view along the XXIBY-XXIBY line depicted in FIG. 21A. FIG. 21C is a section view along the XXICX-XXICX line depicted in FIG. 21A.

As depicted in FIGS. 21B and 21C, an insulating film 104 (for example, SiO film or SiN film) of 25 nm-100 nm (preferably, 50 nm) in thickness is deposited on the flattened polysilicon film 102.

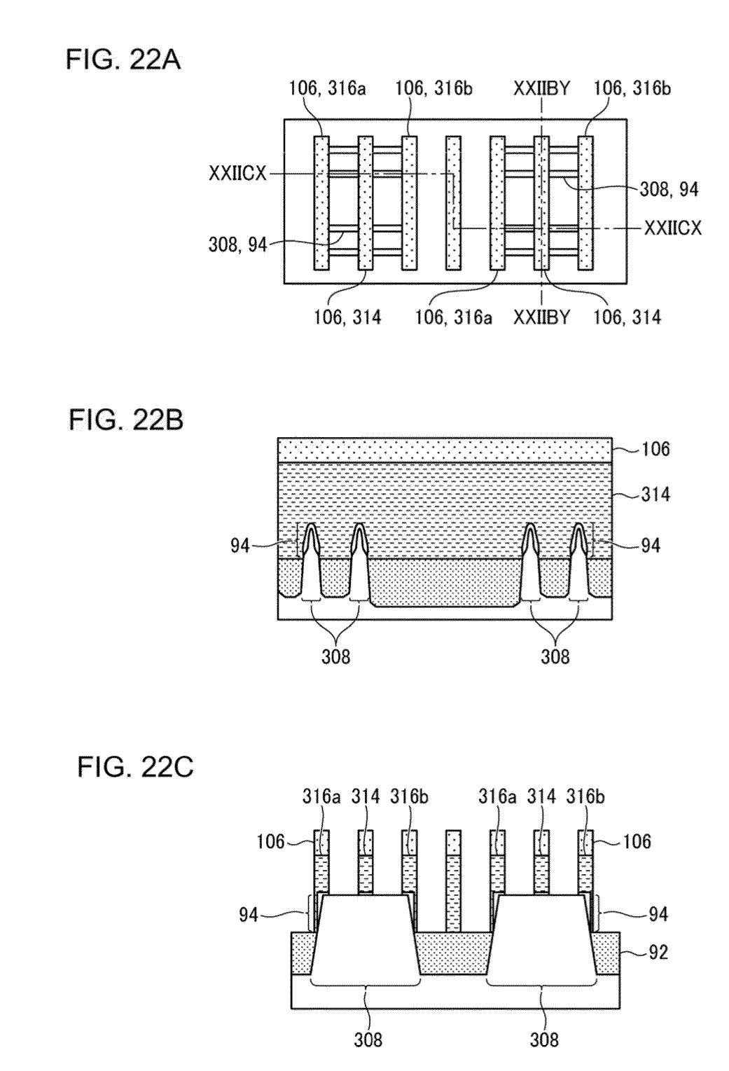

FIG. 22A is a plan view illustrating the forming process of the temporary gate electrodes and the dummy gate electrodes. FIG. 22B is a section view along the XXIIBY-XXIIBY line depicted in FIG. 22A. FIG. 22C is a section view along the XXIICX-XXIICX line depicted in FIG. 22A.

On the insulating film 104 (refer to FIGS. 21B and 21C), resist patterns (not illustrated) that have a certain width (for example, 20 nm-35 nm) and extend to a certain direction (for example, the [1-11] direction of the semiconductor substrate 2) are formed with a certain pitch by means of immersion ArF lithography, for example. Through the resist patterns, the insulating film 104 on the polysilicon film is etched to form hard masks 106 (refer to FIGS. 22A to 22C).

Through these hard masks 106, the polysilicon film 102 (refer to FIGS. 21B and 21C) is etched by RIE, for example. Consequently, on the semiconductor regions 308 including the Fins 94 on the tops, formed are temporary gate electrodes 314, first dummy gate electrodes 316a located on first sides of the temporary gate electrode 314, and second dummy gate electrodes 316b located on second sides different from the first sides of the temporary gate electrodes 314. Here, as depicted in FIG. 22C, the semiconductor region 308 extends in a direction from the first dummy gate electrodes 316a toward the temporary gate electrode 314.

Now, the first dummy gate electrode 316a and the second dummy gate electrode 316b are preferably configured to extend across a boundary between the semiconductor region 308 and the plasma oxide film 92, as depicted in FIG. 22C. This enables easy growth of a SiC layer and a SiGe layer described later.

Next, parts of the thermal oxide films that cover the surfaces of the Fins are removed by Wet etching. Here, the removed parts of the thermal oxide films are parts exposed by the RIE.

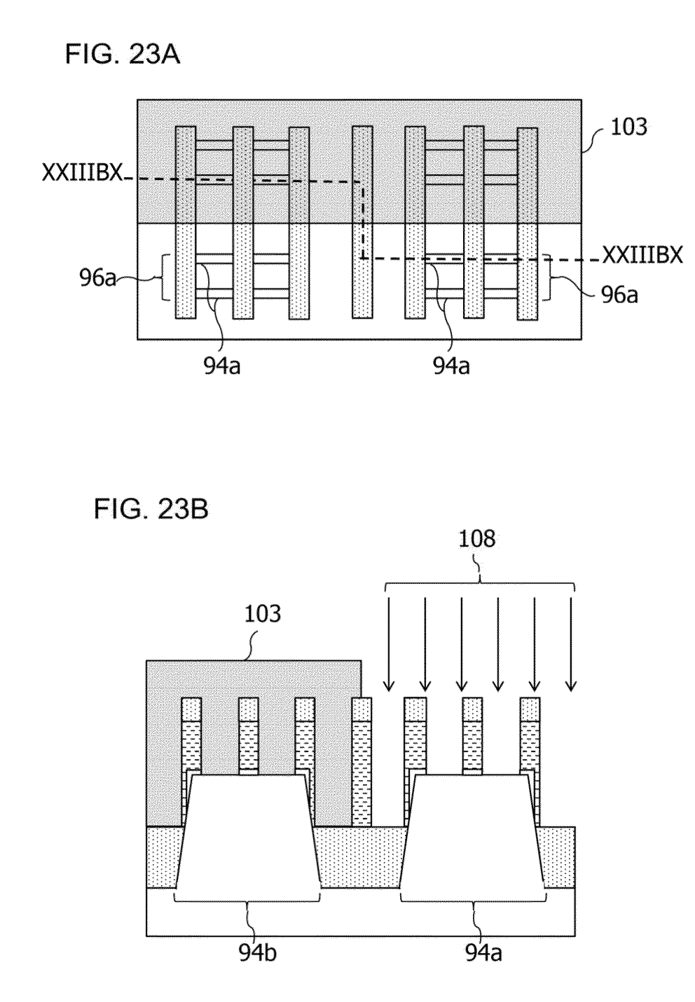

(1-4) Forming Process of Extension Regions and Pocket Regions (Refer to FIGS. 23A and 23B)

FIG. 23A is a plan view illustrating the forming process of extension regions and pocket regions. FIG. 23B is a section view along the XXIIIBX-XXIIIBX line depicted in FIG. 23A.

First, as depicted in FIG. 23B, ions of an n-type impurity (for example, As) are shallowly injected into the Fins 94 (hereafter referred to as a Fins 94a) formed in the first transistor region 96a (refer to FIG. 15), through a resist pattern 103 provided with an aperture on the first transistor region 96a (that is, extension injection). Further, ions of p-type impurity (for example, B) are obliquely injected into the Fins 94a (that is, pocket injection).

Next, ions of a p-type impurity (for example, B) are shallowly injected into the Fins 94 (hereafter referred to as a Fins 94b) formed in the second transistor regions 96b (refer to FIG. 15), through a resist pattern (not illustrated) provided with an aperture on the second transistor regions 96b (that is, extension injection). Further, ions of an n-type impurity (for example, As) are obliquely injected into the Fins 94b (that is, pocket injection).

Thereafter, heat treatment of the Fins 94a and the Fins 94b (for example, spike anneal of 1000° C. or lower) is performed to activate the injected impurity and restore damage in the Fins 94a and the Fins 94b.

Thus, the extension region (not illustrated) and the pocket region (not illustrated) are formed.

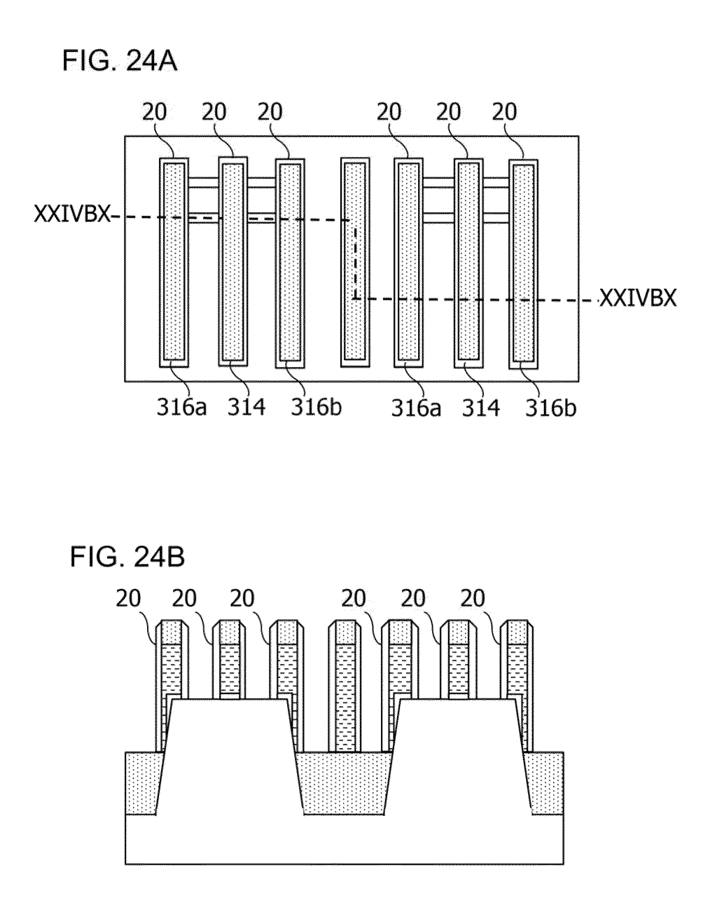

(1-5) Forming Process of Source/Drain Regions (Refer to FIGS. 24A-27B)

FIGS. 24A-27B are diagrams illustrating a forming process of source/drain regions.

—Forming of Sidewall (Refer to FIGS. 24A and 24B)—

FIG. 24A is a plan view illustrating a sidewall forming process. FIG. 24B is a section view along the XXIVBX-XXIVBX line depicted in FIG. 24A.

First, as depicted in FIGS. 24A and 24B, sidewalls 20 are formed on the side faces of the temporary gate electrodes 314, the first dummy gate electrodes 316a, and the second dummy gate electrodes 316b. Each sidewall is a SiN film or a SiO film of 10 nm-20 nm in thickness, for example.

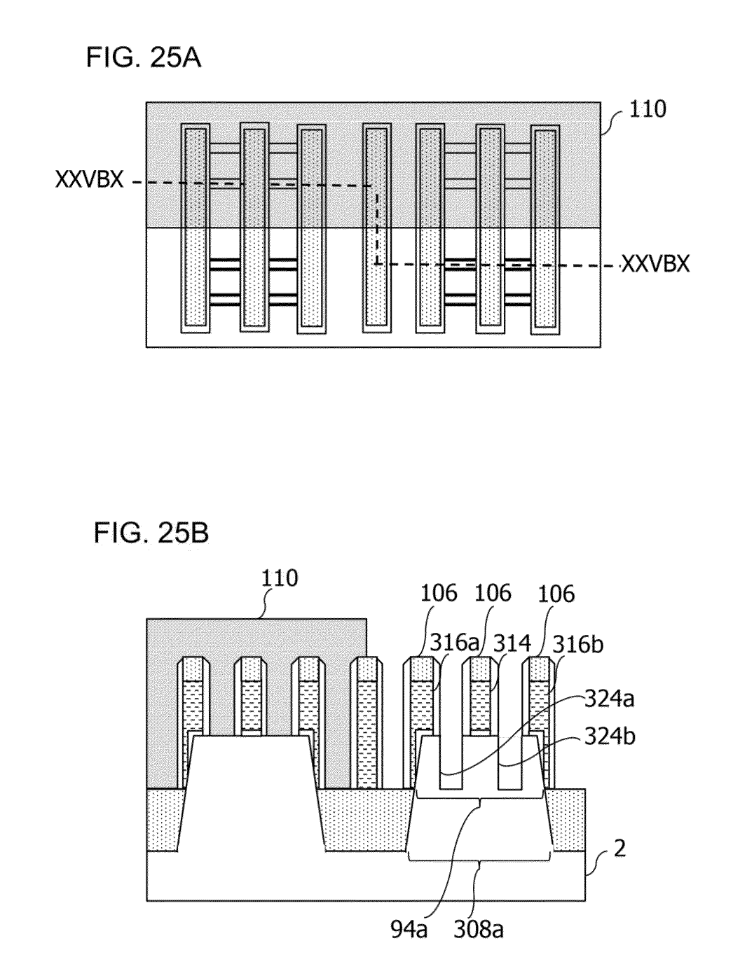

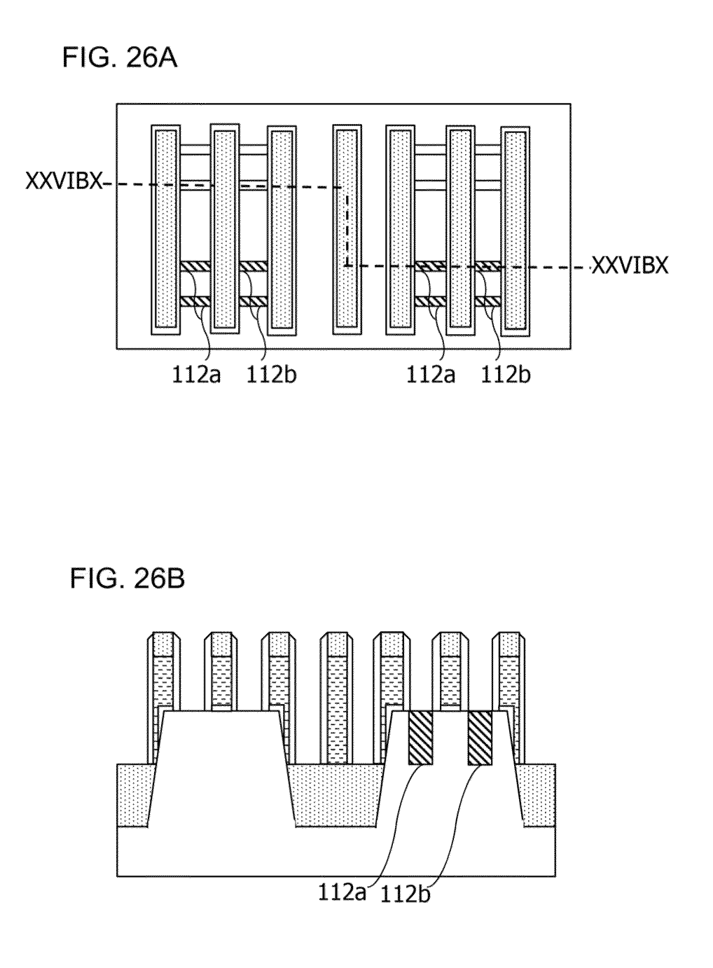

—Forming of SiC Layer in the First Transistor Region (Refer to FIGS. 25A-26B)—

FIG. 25A is a plan view illustrating forming process of SiC layers in the first transistor region 96a (refer to FIG. 15). FIG. 25B is a section view along the XXVBX-XXVBX line depicted in FIG. 25A.

First, on the Si substrate 2 on which the sidewalls 20 are formed, a SiO film (not illustrated) of 2 nm-5 nm in thickness and a SiN film (not illustrated) of 10 nm-40 nm in thickness are deposited in this order, to form a SiO/SiN film. On the SiO/SiN film, a resist pattern (not illustrated) provided with an aperture on the first transistor region 96a is formed. The SiO/SiN film is then etched through the resist pattern to form a hard mask 110 (refer to FIGS. 25A and 25B).

Through the above hard mask 110 and hard masks 106 on the polysilicon films, Fins 94a are etched by, for example, dry etching (or the combination of dry etching and wet etching). Consequently, as depicted in FIGS. 25A and 25B, a first recess 324a is provided in a first region between the temporary gate electrode 314 and the first dummy gate electrode 316a in a convex semiconductor region 308a including the Fin 94a on the top. Here, in an example depicted FIGS. 25A and 25B, a plurality of first recesses 324a are provided. Further, a second recess 324b is provided in a second region on the second side of the temporary gate electrode 314 in a convex semiconductor region 308a including the Fin 94a on the top. Here, the second side is different from the first side. In other words, the second recess 324b is provided in the second region between the temporary gate electrode 314 and the second dummy gate electrode 316b in the semiconductor region 308a. Here, in an example depicted FIGS. 25A and 25B, a plurality of second recesses 324b are provided.

FIG. 26A is a plan view illustrating a forming process of SiC layers in the first transistor region. FIG. 26B is a section view along the XXVIBX-XXVIBX line depicted in FIG. 26A.

After the forming of the first recesses 324a and the second recesses 324b, SiC layers 112a, 112b are epitaxially grown in the first recesses 324a and the second recesses 324b with substantially the same procedure as in the embodiment 1. Thereafter, the hard mask 110 (refer to FIG. 25A) is removed.

Thus, the SiC layers 112a (first semiconductor layers), which have a second lattice constant smaller than the first lattice constant of the convex semiconductor regions 308a, are formed in the first recesses 324a (refer to FIG. 25B). Also, the SiC layers 112b (second semiconductor layers), which have second lattice constant smaller than the first lattice constant of the convex semiconductor regions 308a, are formed in the second recesses 324b (refer to FIG. 25B). The SiC layers 112a, 112b become the source and drain regions of the strained channel NMOS transistors (n-channel Fin Field Effect Transistor).

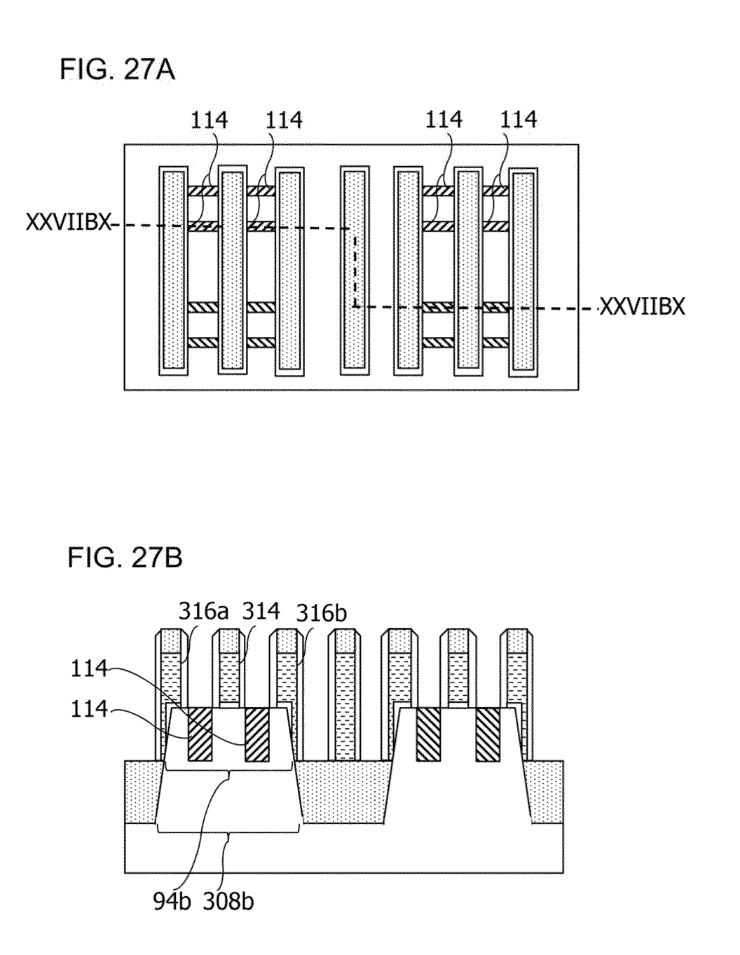

—Forming of SiGe Layers in the Second Transistor Region (Refer to FIGS. 27A and 27B)—

FIG. 27A is a plan view illustrating a forming process of SiGe layers in the second transistor region 96b (refer to FIG. 15). FIG. 27B is a section view along the XXVIIBX-XXVIIBX line depicted in FIG. 27A.

First, recesses are provided between the temporary gate electrodes 314 and the first dummy gate electrodes 316a in the convex semiconductor regions 308b provided with the Fins 94b formed on the tops. At same time, other recesses are provided between the temporary gate electrodes 314 and the second dummy gate electrodes 316b in the convex semiconductor regions 308b provided with the Fins 94b formed on the tops. The above recesses may be formed through substantially the same procedure as the forming process of the first recesses 324a and the second recesses 324b described by reference to FIGS. 25A and 25B.

Next, SiGe layers 114 are epitaxially grown in the formed recesses through substantially the same procedure as in the embodiment 2.

Thus, the SiGe layers 114, which have a second lattice constant larger than the first lattice constant of the convex semiconductor regions 308b (Si regions), are formed in the recesses provided on both sides of the temporary gate electrodes 314. The SiC layers 114 become the source and drain regions of the strained channel PMOS transistors (p-channel Fin Field Effect Transistors).

—Impurity Injection into SiC Layer—

Next, ions of an n-type impurity (for example, P or As) are injected into the SiC layers 112a, 112b (the first and second semiconductor layers) of the first transistor region 96a. The above ion injection may be performed through a resist pattern provided with an aperture in the first transistor region 96a. Further, ions of a p-type impurity (for example, B) are injected into the SiGe layers 114 (the first and second semiconductor layers) of the second transistor region 96b. The above ion injection may be performed through a resist pattern provided with an aperture on the second transistor region 96b.

Thereafter, heat treatment of the SiC layers 112a, 112b and the SiGe layers 114 (for example, spike anneal at 1000° C. or lower) is performed to activate the injected impurities and restore damage in the SiC layers 112a, 112b and the SiGe layers 114.

Here, instead of injecting the n-type impurity ions into the SiC layers 112a, 112b, it may also be possible to epitaxially grow SiC layers including an n-type impurity element (for example, P), using a source gas to which a gas (for example, PH₃) including an n-type impurity element is added. Also, instead of injecting the p-type impurity ions into the SiGe layers 114, it may also be possible to epitaxially grow SiGe layers 114 including a p-type impurity element (for example, B), using a source gas to which a gas (for example, B₂H₆) including a p-type impurity element is added.

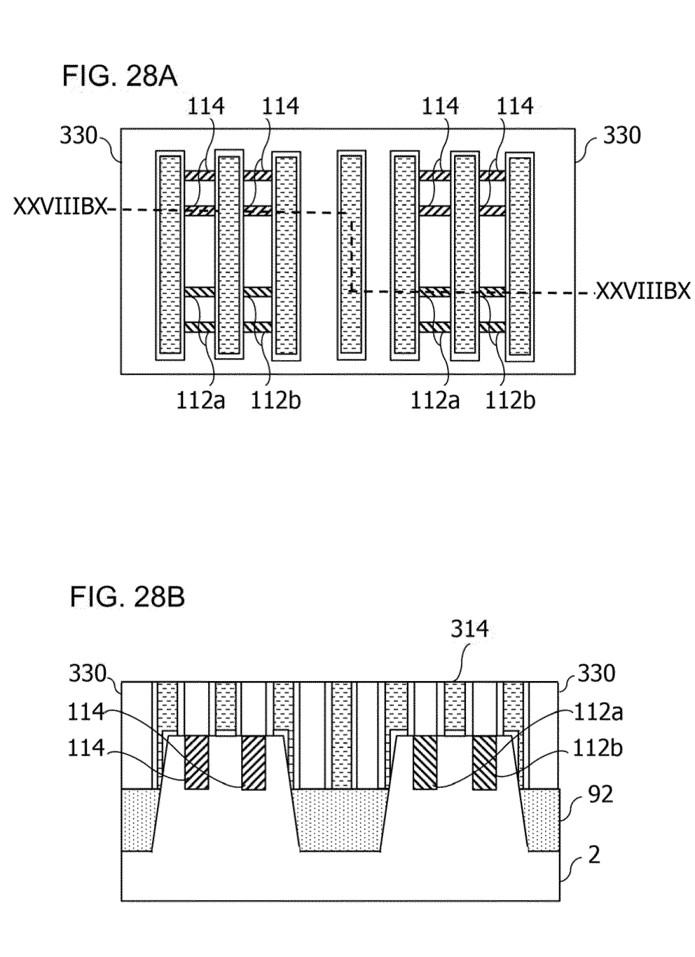

(1-6) Forming Process of Gate Electrodes (Refer to FIGS. 28A-32B)

—Forming of CESL and Interlayer Insulating Film (Refer to FIGS. 28A-28B)—

FIG. 28A is a plan view illustrating a forming process of a CESL and an interlayer insulating film. FIG. 28B is a section view along the XXVIIIBX-XXVIIIBX line depicted in FIG. 28A.

Through the same procedure as described by reference to FIG. 8B in the embodiment 1, a CESL (not illustrated) and an interlayer insulation layer 330 are formed on the Si substrate 2 on which the SiC layers 112a, 112b and the SiGe layers 114 are formed (refer to FIGS. 28A and 28B).

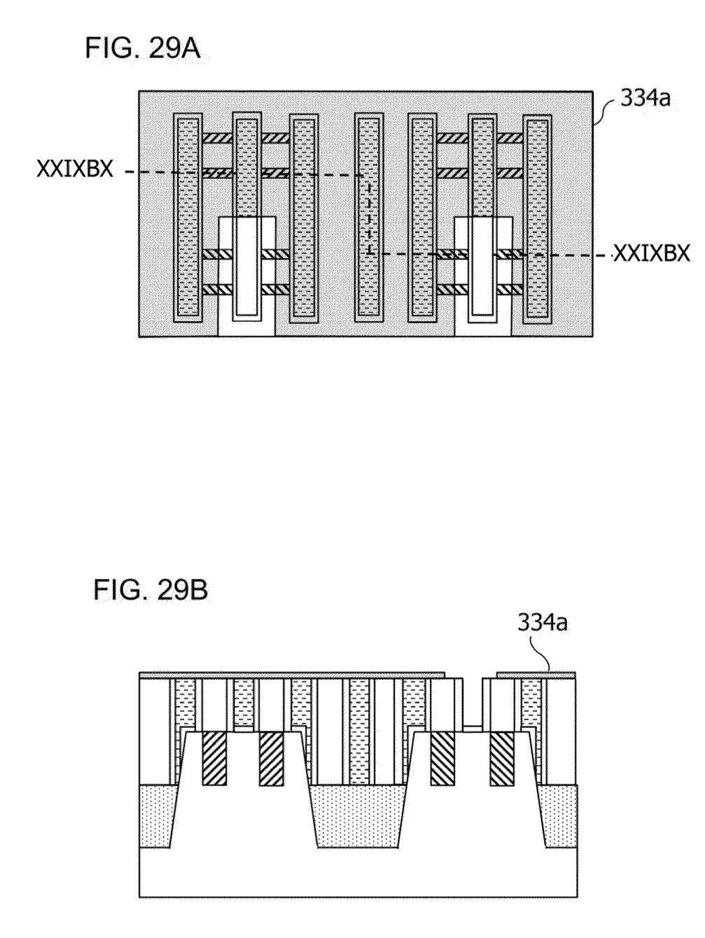

—Removing of Temporary Gate Electrodes in the First Transistor Region (Refer to FIGS. 29A-29B)

FIG. 29A is a plan view illustrating a method for removing the temporary gate electrode 314 in the first transistor region 96a (refer to FIG. 15). FIG. 29B is a section view along the XXIXBX-XXIXBX line depicted in FIG. 29A.

Here, the temporary gate electrodes 314 are removed through substantially the same procedure as the procedure described by reference to FIGS. 3C-4A and FIGS. 8C-9A in the embodiment 1. More specifically, first, a hard mask 334a (refer to FIGS. 29A and 29B) exposing the top faces of the temporary gate electrodes 314 (refer to FIG. 28B) is formed in the first transistor region 96a. Thereafter, through the hard mask 334a, the temporary gate electrodes 314 are etched (refer to FIGS. 29A and 29B).

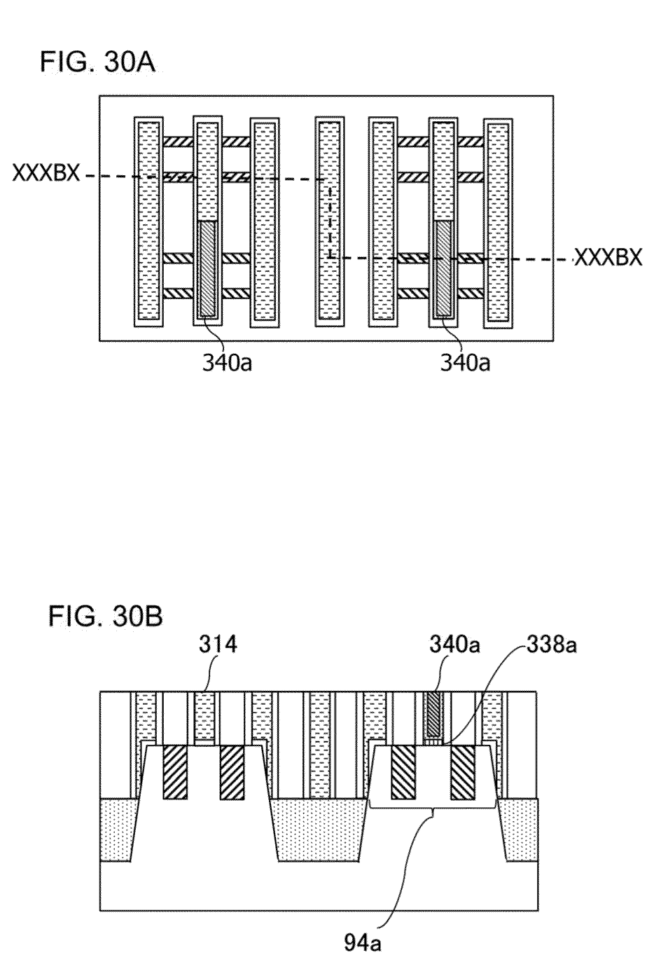

—Forming of Gate Electrodes in the First Transistor Region (Refer to FIGS. 30A-30B)—

FIG. 30A is a plan view illustrating a forming process of gate electrodes in the first transistor region 96a (refer to FIG. 15). FIG. 30B is a section view along the XXXBX-XXXBX line depicted in FIG. 30A.

Through substantially the same procedure as the procedure described by reference to FIGS. 4B and 9B in the embodiment 1, gate insulating films 338a and gate electrodes 340a are formed in the regions from which the temporary gate electrodes 314 are removed (refer to FIGS. 30A-30B). At this time, the gate insulating films 338a and the gate electrodes 340a cover the side faces of the Fins 94a.

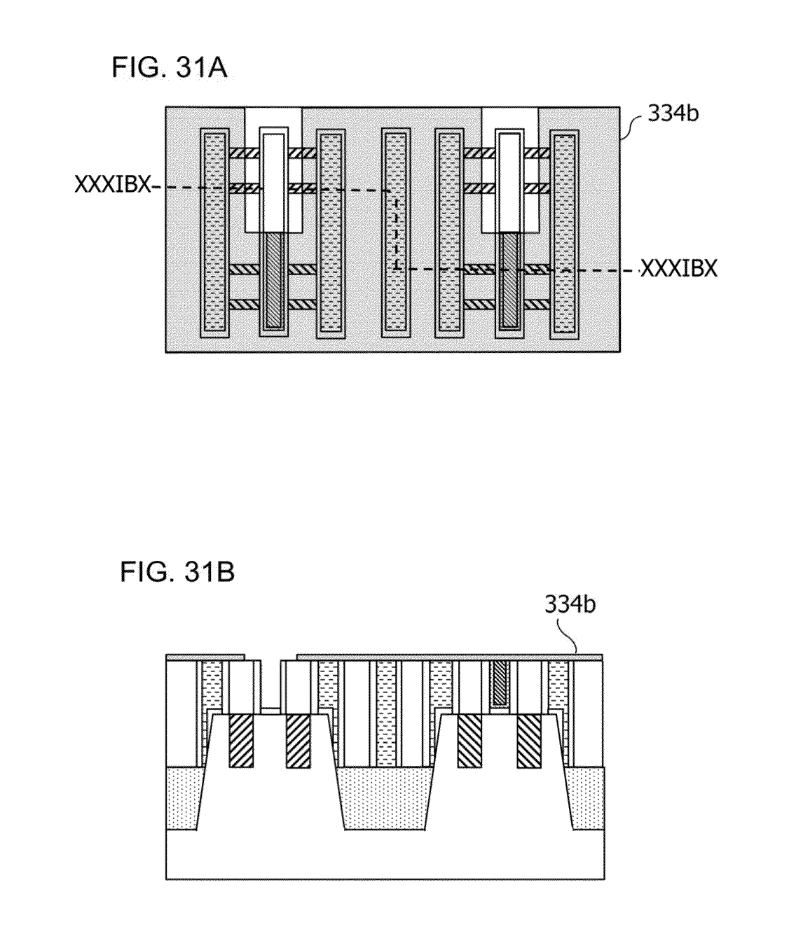

—Removing of Temporary Gate Electrodes in the Second Transistor Regions (Refer to FIGS. 31A-31B)—

FIG. 31a is a plan view illustrating a method of removing the temporary gate electrodes 314 in the second transistor regions 96b (refer to FIG. 15). FIG. 31B is a section view along the XXXIBX-XXXIBX line depicted in FIG. 31A.

Here, the temporary gate electrodes 314 (refer to FIG. 30B) in the second transistor region 96b (refer to FIG. 15) is removed by substantially the same procedure as the removing method of the temporary gate electrode 314 in the first transistor region 96a (refer to FIGS. 29A-29B).

More specifically, first, a hard mask 334b (refer to FIGS. 31A and 31B) exposing the top faces of the temporary gate electrodes 314 is formed in the second transistor region 96b. Thereafter, through the hard mask 334b, the temporary gate electrodes 314 is etched (refer to FIGS. 31A and 31B).

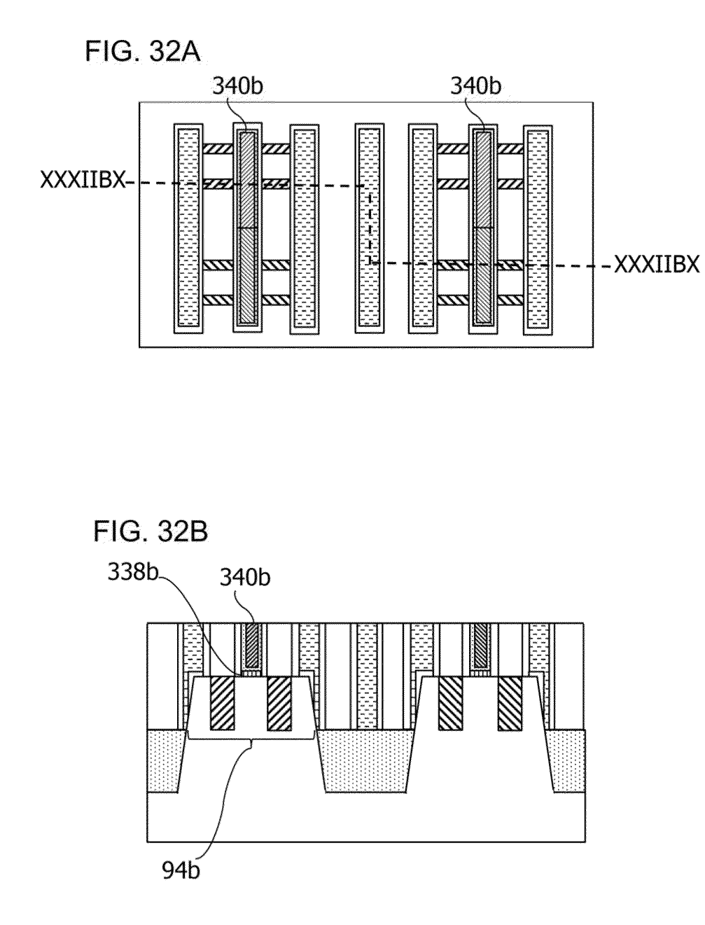

—Forming of Gate Electrode in the Second Transistor Region (Refer to FIGS. 32A-32B)—

FIG. 32A is a plan view illustrating a forming process of gate electrodes in the second transistor region 96b (refer to FIG. 15). FIG. 32B is a section view along the XXXIIBX-XXXIIBX line depicted in FIG. 32A.

Through substantially the same procedure as in the gate electrode forming method (refer to FIGS. 30A and 30B) in the first transistor region 96a, gate insulating films 338b and gate electrodes 340b are formed in the regions from which the temporary gate electrodes 314 are removed (refer to FIGS. 32A-32B). At this time, the gate insulating films 338b and the gate electrodes 340b cover the side faces of the Fins 94b.

(1-7) Forming Process of Contact and Waiting Layer

Finally, a wiring layer and vias are formed by substantially the same procedure as the procedure in the “(1-8) Forming process of contact and wiring layer (refer to FIGS. 4C to 5 and FIGS. 9C to 10)”. Thus, the semiconductor device according to the embodiment 3 is completed.

(2) Structure and Operation

In the semiconductor device according to the embodiment 3, each width of the Fin 94a and the Fin 94b on which the strained channel MOS Field Effect Transistor is formed is quite narrow, and further, the side faces of the Fin 94a and the Fin 94b are covered with the gate insulating films 338a, 338b and gate electrodes 340a, 340b. Therefore, according to the embodiment 3, a short-channel effect of the strained channel MOS Field Effect Transistor is suppressed, in addition to improved mobility in the channel region of the strained channel MOS Field Effect Transistor.

Except for the above points, the structure and the operation of the semiconductor device according to the embodiment 3 is substantially the same as the structure and the operation of the semiconductor device according to the embodiment 1 or 2.

### (3) Modified Example

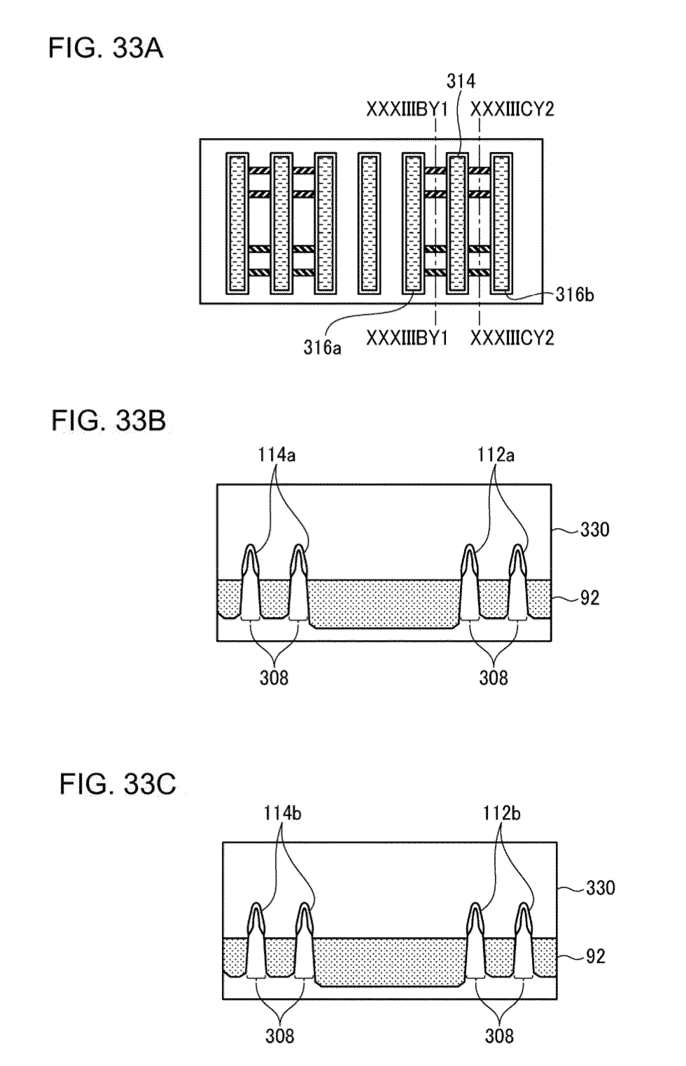

FIG. 33A is a plan view illustrating a modified example of the embodiment 3. FIG. 33B is a section view along the XXXIIIBY1-XXXIIIBY1 line depicted in FIG. 33A. FIG. 33C is a section view along the XXXIIICY2-XXXIIICY2 line depicted in FIG. 33A.

In the aforementioned examples, on the semiconductor regions 308 having a convex cross section and extending to one direction, the recesses are provided to form the SiC layers (or SiGe layers) therein. However, as depicted in FIG. 33B, in first regions between the temporary gate electrodes 314 and the first dummy gate electrodes 316a in the semiconductor regions 308, it may also be possible to form first semiconductor layers (SiC layers 112a and SiGe layers 114a) that cover at least the tops of the first regions, instead of providing the recesses between the temporary gate electrodes 314 and the first dummy gate electrodes 316a. Further, as depicted in FIG. 33C, in second regions between the temporary gate electrodes 314 and the second dummy gate electrodes 316b in the semiconductor regions 308, it may also be possible to provide second semiconductor layers (SiC layers 112b and SiGe layers 114b) that cover at least the tops of the second regions. In FIG. 33, depicted is a state before the temporary gate electrodes 314 is removed.

The embodiments 1-3 are merely exemplified and not restrictive. For example, each semiconductor device according to the embodiments 1-3 includes the second semiconductor layer. However, it may also be possible to form the semiconductor device of the embodiment 1-3 without the second semiconductor layer. In this case also, a strain increase in the semiconductor regions 8, 308 due to the removing of the gate-shaped electrodes may be concentrated in the channel region by the removing of only the temporary gate electrodes 14, 314.

Further, it may be possible to form the semiconductor device of the embodiments 1-3 without the second dummy gate electrodes 16b, 316b. In this case also, a strain increase in the semiconductor regions 8, 308 due to the removing of the gate-shaped electrodes may be concentrated in the channel region by the removing of only the temporary gate electrodes 14, 314.

Further, in the embodiments 1-3, the high-dielectric-constant film is formed after the removing of the temporary gate electrodes 14, 314. However, it may also be possible to form the high-dielectric-constant film before the forming of the temporary gate electrodes 14, 314.

In the embodiments 1-3, the material of the semiconductor regions 8, 308 is Si. However, another material (for example, Ge) may be used as the material of the semiconductor regions 8, 308. When the material of the semiconductor regions 8, 308 is p-type Ge, preferably, the material of the first semiconductor layer and the second semiconductor layer is SiGe. When the material of the semiconductor regions 8, 308 is n-type Ge, preferably, the material of the first semiconductor layer and the second semiconductor layer is a mixed crystal of germanium (Ge) and tin (Sn).

Also, in the embodiments 1-3, the material of the gate electrode 40 is metal. However, another material (for example, polysilicon) may be used as the material of the gate electrode 40.

Further, in the embodiments 1-3, the material of the first dummy gate electrodes 16a, 316a and the second dummy gate electrodes 16b, 316b is polysilicon. However, another material (for example, metal) may be used as the material of the first dummy gate electrodes 16a, 316a and the second dummy gate electrodes 16b, 316b

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A method for manufacturing a semiconductor device comprising:
forming a temporary gate electrode and a first dummy gate electrode located on a first side of the temporary gate electrode, on a semiconductor region with a first lattice constant;
forming a first semiconductor layer with a second lattice constant different from the first lattice constant, between the temporary gate electrode and the first dummy gate electrode;
removing the temporary gate electrode while leaving the first dummy gate electrode intact; and
forming a gate electrode in a region from which the temporary gate electrode is removed.

2. The method for manufacturing a semiconductor device according to claim 1, further comprising:
providing a first recess in a first region between the temporary gate electrode and the first dummy gate electrode in the semiconductor region before the forming the first semiconductor layer, wherein
the forming the first semiconductor layer includes forming the first semiconductor layer in the first recess.

3. The method for manufacturing a semiconductor device according to claim 2, wherein
the providing the first recess further includes providing a second recess in a second region on a second side of the temporary gate electrode in the semiconductor region, the second side being different from the first side; and
the forming the first semiconductor layer includes forming a second semiconductor layer with the second lattice constant in the second recess.

4. The method for manufacturing a semiconductor device according to claim 3, wherein
the forming the temporary gate electrode and the first dummy gate electrode further includes forming a second dummy gate electrode on the second side of the temporary gate electrode; and
the forming the gate electrode includes removing the temporary gate electrode while leaving the first dummy gate electrode and the second dummy gate electrode intact, and thereafter forming the gate electrode,
wherein the second semiconductor layer is located between the gate electrode and the second dummy gate electrode.

5. The method for manufacturing a semiconductor device according to claim 3, wherein
the first semiconductor layer and the second semiconductor layer are semiconductor layers formed by an epitaxial growth method.

6. The method for manufacturing a semiconductor device according to claim 1, wherein
when a transistor that includes the gate electrode is an n-channel transistor, the second lattice constant is smaller than the first lattice constant, and
when a transistor that includes the gate electrode is a p-channel transistor, the second lattice constant is larger than the first lattice constant.

7. The method for manufacturing a semiconductor device according to claim 1, wherein
the semiconductor region is a convex region that extends in a direction from the first dummy gate electrode toward the temporary gate electrode, and
the forming the first semiconductor layer includes forming the first semiconductor layer that covers at least a top of a first region between the temporary gate electrode and the first dummy gate electrode, the first region being in the semiconductor region.

8. A semiconductor device comprising:
a semiconductor region with a first lattice constant;
a gate electrode that is disposed on the semiconductor region and includes a first gate electrode material;
a first dummy gate electrode that is disposed on a first side of the gate electrode on the semiconductor region and includes a second gate electrode material different from the first gate electrode material; and
a first semiconductor layer that is disposed between the first dummy gate electrode and the gate electrode and has a second lattice constant different from the first lattice constant.

9. The semiconductor device according to claim 8, wherein
the first semiconductor layer is disposed in a first recess provided in a first region between the gate electrode and the first dummy gate electrode, the recess being in the semiconductor region.

10. The semiconductor device according to claim 8,
wherein the first gate electrode material is metal.

11. The semiconductor device according to claim 9, further comprising:
a second semiconductor layer that is disposed in a second recess provided in a second region on a second side of the gate electrode different from the first side and has the second lattice constant, the second region being in the semiconductor region.

12. The semiconductor device according to claim 11, further comprising:
a second dummy gate electrode that is disposed on the second side and includes the second gate electrode material,
wherein the second semiconductor layer is located between the gate electrode and the second dummy gate electrode.

13. The semiconductor device according to claim 11,
wherein the first semiconductor layer and the second semiconductor layer are semiconductor layers formed by an epitaxial growth method.

14. The semiconductor device according to claim 8,
wherein, when a transistor that includes the gate electrode is an n-channel transistor, the second lattice constant is smaller than the first lattice constant, and
when a transistor that includes the gate electrode is a p-channel transistor, the second lattice constant is larger than the first lattice constant.

15. The semiconductor device according to claim 8,
wherein the semiconductor region is a convex region that extends in a direction from the first dummy gate electrode toward the gate electrode, and
wherein the first semiconductor layer covers at least a top of a first region between the temporary gate electrode and the first dummy gate electrode, the first region being in the semiconductor region.
